(19) United States
(12) Patent Application Publication
(10) Pub. No.: US 2024/0160800 A1
(43) Pub. Date: May 16, 2024

(54) Simulation of Parts and Assemblies in a Computer Aided Design Modeling Environment

(71) Applicant: PTC Inc., BOSTON, MA (US)

(72) Inventors: Christopher L. Gromek, Austin, TX (US); Joseph B. Alford, Longmont, CO (US); Gregory D. Brown, Waltham, MA (US); Adam Chacon, Thornton, CO (US); Jonathan D. Hiller, Boulder, CO (US); George R. Hudetz, Erie, CO (US); Tej Kumar, Broomfield, CO (US); Joshua A. Natarajan, Chestnut Hill, MA (US); K Evan Nowak, Northfield, MN (US); James Olliff, Denver, CO (US)

(21) Appl. No.: 18/423,270

(22) Filed: Jan. 25, 2024

Related U.S. Application Data
(63) Continuation of application No. 18/484,437, filed on Oct. 10, 2023.
(60) Provisional application No. 63/378,995, filed on Oct. 10, 2022.

(51) Int. Cl. G06F 30/17

(52) U.S. Cl. CPC G06F 30/17

(57) ABSTRACT

The disclosed simulation environment, methods, and system support simultaneous design and analysis of assemblies with unified computer aided design (CAD) and finite element analysis (FEA). The system provides a simulation environment that is unified with the architecture of the assembly environment, which significantly reduces the amount of time it takes to set up structural simulations as compared to prior simulation tools. The system enables CAD designers to obtain accurate mechanical guidance such as strength and rigidity early and often in the design process, seeing the structural impact of CAD modifications at the sketch, part, and configuration level. Such guidance can be particularly helpful when CAD engineers are determining product fit and form, defining dimensions, and shaping the overall weight and volume of designs.

### RELATED APPLICATIONS

The subject matter of this application is related to U.S. Provisional Application No. 63/378,995, filed on 2022 Oct. 10, U.S. patent application Ser. No. 15/052,418, filed on 2016 Feb. 24, now U.S. Pat. No. 10,437,938, and U.S. patent application Ser. No. 14/226,042, filed on 2014 Mar. 26, now U.S. Pat. No. 9,741,157, all of which applications are incorporated herein by reference in their entireties.

### BACKGROUND OF THE INVENTION

Computer aided design (CAD) is a type of software that enables users to design real-world objects, such as machines and other commercial products. Typical CAD users are designers, engineers, or individuals who want to precisely and efficiently create product designs that represent physical objects.

Simulation or computer aided engineering (CAE) is a computational approach used to mimic real world behavior so designers and engineers can understand how products will perform in real world conditions. One of the most common types of simulation is known as finite element analysis (FEA). FEA simulation helps product designers by emulating a product's behavior before it has been manufactured. Consider the design of your local playground swing set. The steel bar and brackets which hold the swings are rated for a maximum weight (or load), which is typically 250 lbs. Structural simulation can be used to determine the max load the swing can take before deformations occur. Product designers today, who are driven to be agile, need to consider engineering requirements, such as safety factor (ratio of materials strength to strain from load), to ensure safe designs and proper quality, performance and lifespan. The benefits of simulation for CAD designers can include, for example, arriving at a final design which meets requirements sooner, reducing waste in time and materials, revisioning fewer prototypes prior to production, and avoiding problematic designs where safety or quality could be an issue.

### SUMMARY OF THE INVENTION

The disclosed system and methods support simultaneous design and analysis of assemblies with unified design and simulation. The system unifies a CAE simulation environment with the architecture and user interface of a CAD modeling environment, which significantly reduces the amount of time it takes to set up structural simulations as compared to prior simulation tools. The unified simulation and CAD modeling environment enables a designer to perform a simulation without ever having to navigate away from the CAD environment. The system enables CAD designers to obtain accurate mechanical guidance such as strength and rigidity early and often in the design process, seeing the structural impact of CAD modifications at the sketch, part, and configuration level. Such guidance can be particularly helpful when CAD engineers are determining product fit and form, defining dimensions, and shaping the overall weight and volume of designs.

Compared to prior integrated FEA solutions, the disclosed approach delivers equivalently accurate results while requiring significantly fewer actions to set up the simulation environment to solve structural analysis problems. In integrated CAD-FEA solutions, users need to manually set up part to part connections or inspect an automated set up for correctness. The unified simulation and modeling environment leverages CAD assembly mates as the data model for part to part connections, and no further user actions are required, additionally the environment makes inspecting connections visual, fast, and easy. The system supports complex assembly design and static analysis on the full assembly without ever leaving the design environment. Structural analysis results can be visualized with one action right in an assembly tab.

The disclosed system and environment dramatically reduce the effort required in time and steps for CAD engineers to set up and calculate structural analysis, particularly on a full assembly. Designers need not defeature their model to simplify it or set up pairs of contact. The system can use existing assembly mates in the definition of the part-to-part interactions to offer the designer the most efficient FEA workflow. Simulation can be unified, going beyond prior integrated CAD & FEA solutions where the CAD model is associated with the FEA model. In the disclosed system, simulation occurs directly in the assembly or modeling environment. Simulation data can be made part of the CAD document and can be stored with a model's design history. The system can support simultaneous design and analysis of assemblies. Simulation requires no pre-processing or meshing, allowing users to explore design variations quickly. When a user modifies a CAD model, the simulation results can refresh automatically.

A method can be performed by a computer system having at least one processor and a memory. The method can include: maintaining in the memory a computer-aided design (CAD) model representing a plurality of components of a modeled object; receiving a user request to perform a simulation on or of the CAD model, the user request being received through a unified simulation and CAD modeling environment; performing an automated analysis of the CAD model to identify portions of the model that have one or more restricted degrees of freedom; and performing a simulation on the CAD model, wherein the simulation accounts for the one or more restricted degrees of freedom.

The automated analysis of the CAD model can include: identifying portions of different components of the CAD model that are positioned within a predetermined distance of each other within the modeled object; and identifying the one or more restricted degrees of freedom based on the identified portions of different components.

Identifying portions of different components of the CAD model that are positioned within a predetermined distance of each other within the modeled object can include: converting the CAD model from a boundary representation format to a volumetric representation format; and identifying regions where volumetric representations of components intersect.

The method can further include: receiving user input through a CAD user interface, the user input defining one or more loads upon the model; and storing definitions of the one or more loads in as data elements within the CAD model.

The plurality of components can be related in the CAD model by connection points having associated connection types, and the simulation on the CAD model can account for further restricted degrees of freedom based on the connection points and associated connection types.

The simulation can be of a type selected from the group consisting of: structural linear static analysis, and modal analysis.

A method can be performed by a computer system having at least one processor and a memory. The method can include: maintaining a computer-aided design (CAD) model comprising a plurality of components in the memory, wherein the plurality of components are related by connection points having associated connection types; performing an automated analysis to identify portions of different components that are positioned within a predetermined distance within the CAD model; and based on the automated analysis, restricting one or more degrees of freedom of the identified portions of different components in a simulation environment.

A method can be performed by a computer system having at least one processor and a memory. The method can include: maintaining in the memory a computer-aided design (CAD) model representing a plurality of components of a modeled object; receiving a user request to perform a simulation on the CAD model in a unified simulation and CAD modeling environment; performing an automated analysis of the CAD model to identify portions of different components that are positioned within a predetermined distance of each other within the modeled object; based on the automated analysis, restricting one or more degrees of freedom of the identified portions of different components in the unified simulation and CAD modeling environment; and performing a simulation on the CAD model, wherein the simulation accounts for the restricted one or more degrees of freedom.

A computer system can include the at least one processor and the memory, wherein the memory has instructions stored thereon that are executed by the at least one processor and cause the computer system to perform any of the foregoing methods.

A non-transitory computer readable medium can have instructions stored thereon, wherein the instructions are executed by the least one processor and cause the at least one processor to perform any of the foregoing methods.

As will be appreciated by one skilled in the art, multiple aspects described in this summary can be variously combined in different operable embodiments. All such operable combinations, though they may not be explicitly set forth in the interest of efficiency, are specifically contemplated by this disclosure.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a system overview diagram.

FIG. 2 is a flowchart showing the startup process for a server.

FIG. 3 is a flowchart showing the server selection process when opening a project.

FIG. 4 is a flowchart showing server interaction during a typical user edit within a project.

FIG. 5 is a screenshot of the projects overview.

FIG. 6 is a tabbed document screenshot.

FIG. 7 is an upload screenshot.

FIG. 8 is a download screenshot.

FIG. 9 is a translate screenshot.

FIG. 10 is an export screenshot.

FIG. 11 is a properties screenshot.

FIG. 12 is an editing dialog screenshot.

FIG. 13 is a sketching mode screenshot.

FIGS. 14, 15, and 16 are screenshots showing inferences.

FIG. 17 is a flowchart detailing predictive drag.

FIG. 18 is an assembly screenshot.

FIG. 19 is a measuring properties screenshot.

FIG. 20 is a mass properties screenshot.

FIG. 21 shows the history.

FIG. 22 shows the version manager.

FIG. 23 shows sharing a project.

FIG. 24 shows multiple users working simultaneously within the same workspace.

FIG. 25 shows code representation opened while CAD editing.

FIGS. 26A and 26B show part edges defining the edges of another part.

FIG. 27 shows one part with a feature defined by the geometry of another part.

FIG. 28 shows detection of out-of-sync references.

FIG. 29 shows resolving out-of-sync references through synchronizing.

FIG. 30 shows resolving out-of-sync references through dismissing.

FIGS. 31A-C show a user interface for performing simulations of static loads in a CAD environment.

FIGS. 32A-B illustrates a user interface showing the results of a simulation.

FIG. 33 illustrates a Simulation fly-out panel.

FIG. 34 illustrates an expanded view of a Simulation settings section of the Simulation fly-out panel.

FIGS. 35A-C illustrate three examples of the use of the Show connections checklist.

FIGS. 36A-B illustrate a Mate Simulation connection option.

FIGS. 37A-N illustrate a workflow to create and simulate a load on a CAD model.

FIGS. 38A-D illustrate an alternate method to solve a simulation.

FIGS. 39A-B contrast the simulation workflow of the disclosed system and a traditional simulation workflow.

FIG. 40 illustrates a general computer architecture that can be appropriately configured to implement components disclosed in accordance with various embodiments.

### DETAILED DESCRIPTION

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

In the following description, references are made to various embodiments in accordance with which the disclosed subject matter can be practiced. Some embodiments may be described using the expressions one/an/another embodiment or the like, multiple instances of which do not necessarily refer to the same embodiment. Particular features, structures or characteristics associated with such instances can be combined in any suitable manner in various embodiments unless otherwise noted. By way of example, this disclosure may set out a set or list of a number of options or possibilities for an embodiment, and in such case, this disclosure specifically contemplates all clearly feasible combinations and/or permutations of items in the set or list.

### Overview of the Disclosure

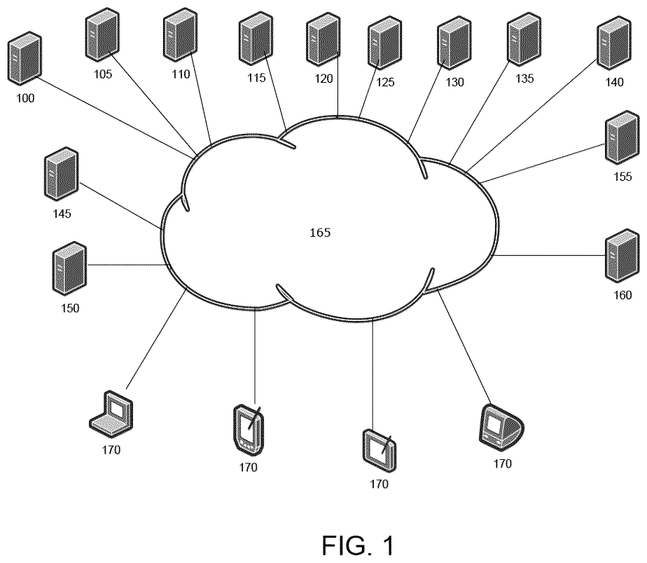

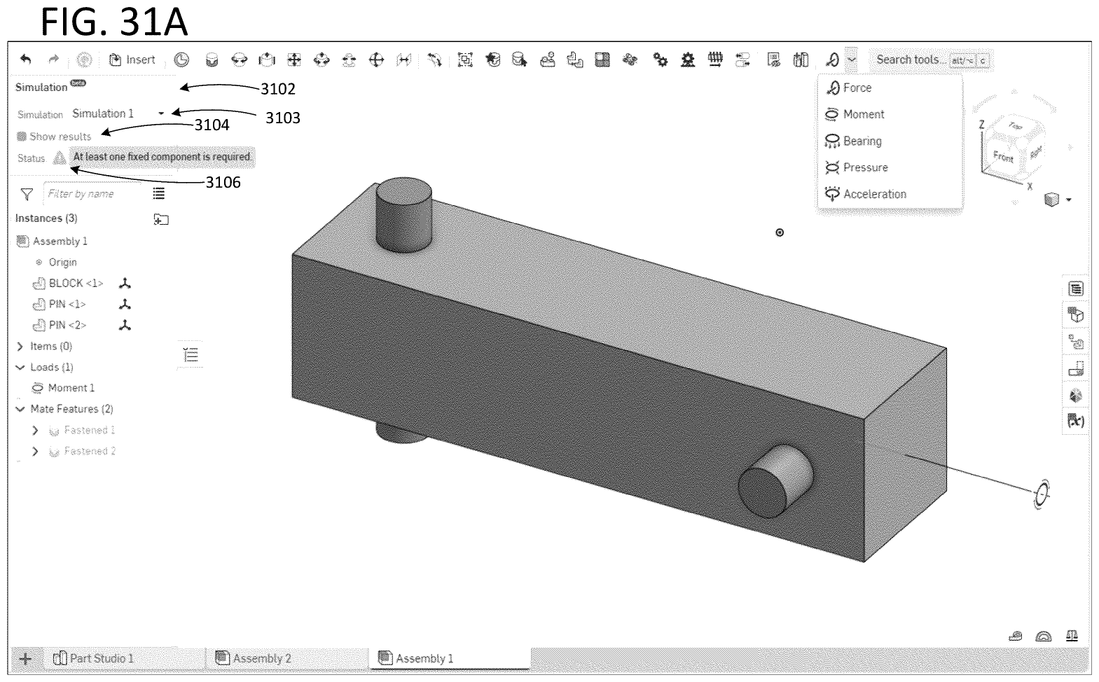

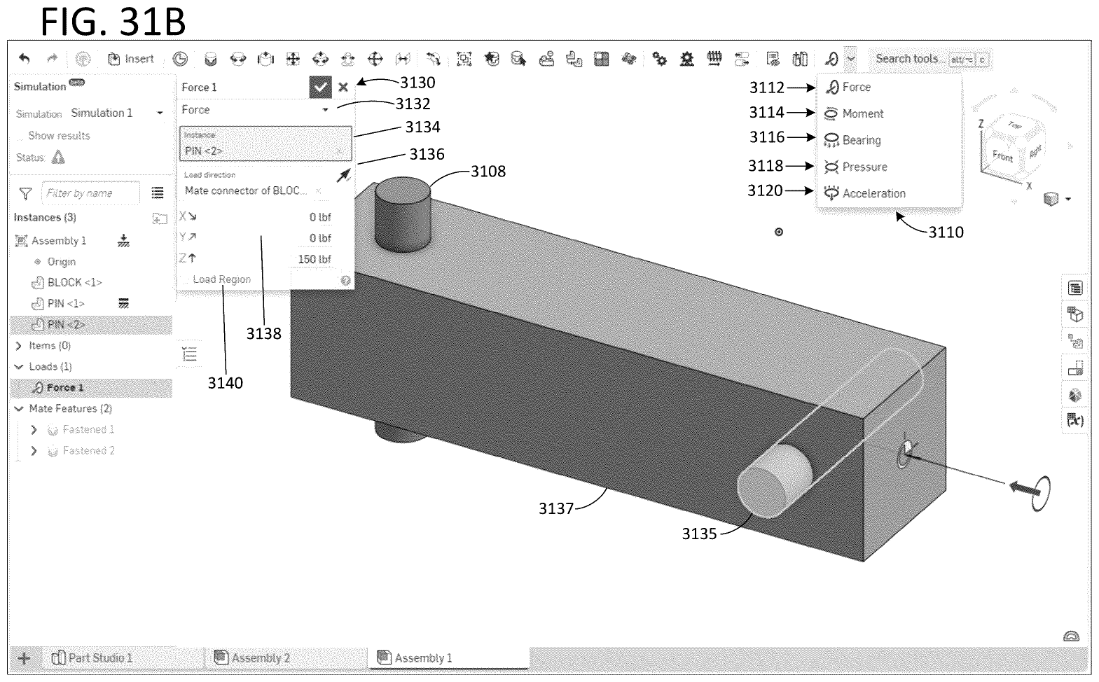

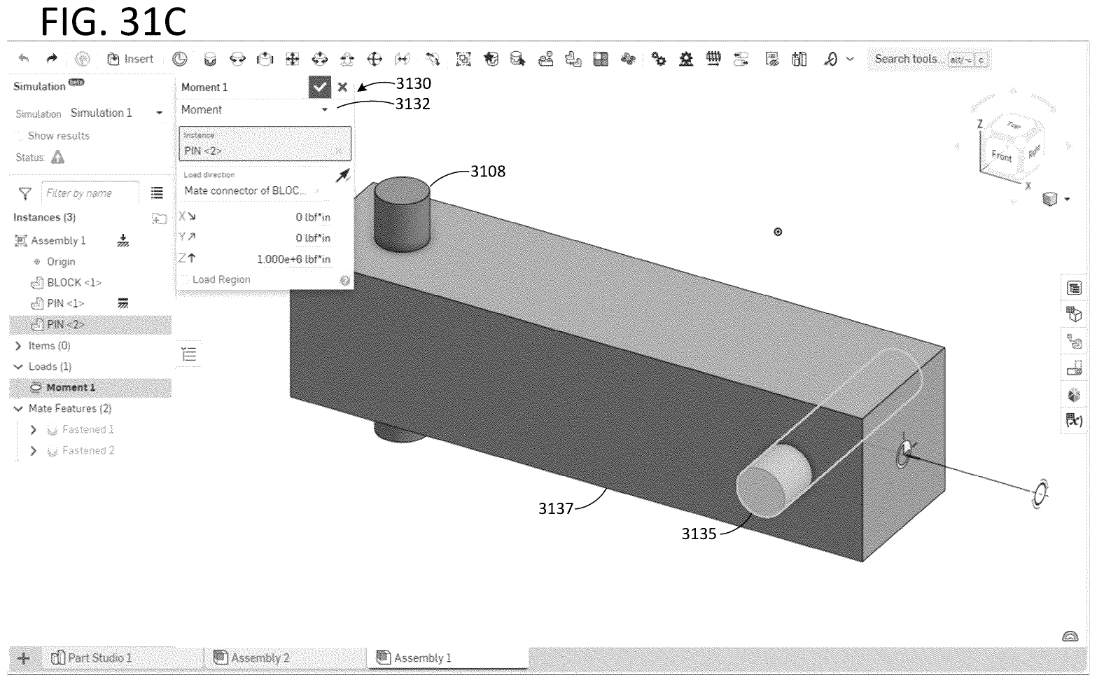

A Multi-User Parametric Feature Based 3D CAD System (“System”) provides a system platform that can be configured to support the disclosed simulation environment and associated methods. The system platform will first be described with reference to FIGS. 1-30 below, and subsequently, in a section titled “SIMULATION OF PARTS AND ASSEMBLIES”, the disclosed simulation environment and associated methods will be described with reference to FIG. 31 et seq. Although the simulation environment and associated methods are described herein with respect to the disclosed system platform, the disclosed concepts can be implemented on other platforms as will be understood by one skilled in the art.

System Platform

The System is constructed in several parts. Sets of computers (“Servers”) perform 3D geometry calculations, manage CAD editing workflow, and manage interactions between user client devices (computers, tablets, phones) and the CAD editing servers. Client programs operate on client computing devices to display a graphical interface for CAD editing. The client program may be a dedicated software program or application stored on the client device or loaded on demand such as within a web browser. A network and system of communication passes asynchronous messages among these Servers and the client software. 3D information flow is optimized for rapid model and change dissemination.

System Overview

Referring to FIG. 1, multiple servers communicate with each other and with client devices. As shown in FIG. 1, such communications occur across internet 165. This is preferred, because it extends use anywhere the internet is accessible, but may alternatively be replaced with any network connecting the servers with each other and to client devices. Similarly, individual servers are shown as separate physical devices. These servers may be combined to run on shared devices, or connected internally, but the depicted configuration is preferred to allow geographic distribution of the various servers. The servers shown may be run in multiple mirrored copies distributed geographically, allowing optimization for user connection and performance regardless of location. Each individual copy of a server may be run on a single physical computer, across multiple physical computers (such as a cluster or server farm) or run on one or more physical computers shared with other servers. Each server preferably has dedicated physical resources of eight or more 64-bit, or better, central processing units (CPUs), with eight or more gigabytes (GB) of memory, and a high-speed one gigabit per second or faster network connection between the various servers, although geographic separation across the internet may slow connections (such as between a client and the servers, or between mirrored servers).

Servers

3D Geometry Calculation Servers (“3DGCS”) 100 run software including, but not limited to, 3d geometry kernels such as, but not limited to, Parasolid or ACTS; 2d and 3d constraint solvers such as, but not limited to, DCubed DCM2D and DCM3D; and other software that performs geometry calculations to modify computer representations of geometric shapes (for example, but not limited to, drilling a hole or rounding edges), that analyzes the shapes (for example, but not limited to, computing volume or surface area), and creates optimized 3D graphics data such as, but not limited to, triangular facets that may be sent to one or more clients via a CAD editing workflow server over a networking protocol in order to display a 3D image of the object being designed.

CAD Editing Workflow Servers (“CEWS”) 105 run software including, but not limited to, an operating system such as Ubuntu or other Linux variant, a web application written in a language such as Java, web application components such as Jetty and Spring, and other software. CEWS receive messages from Client computers and processes over a networking protocol to read and write CAD data from data persistence servers, to perform CAD functions such as modifying CAD features or metadata, coordinate collaboration among users using multiple Clients, and communicate with 3DGCS to do geometric modeling operations for a project. CEWS also, upon request from a Client, send to that Client a set of Client application software such as JavaScript coding that may include 3D WebGL “shader” programs, plus other JavaScript program utilities such as Angular, for operation on the Client device.

Security Credential Management Servers (“SCMS”) 110 run software including, but not limited to, an operating system such as Ubuntu or other Linux variant and software that manages credentials for access to the System. The SCMS is also used to centrally manage authentication credentials and authorization rules for secure access to the computers in the System by operations personnel such as systems administrators.

2D Drawing Editing Workflow Servers (“2DDEWS”) 115 run software including, but not limited to, an operating system such as Ubuntu or other Linux variant and other software that allows Clients to create and manipulate 2D drawings of their CAD models. The software allows the user to create drawings with cutaway views, precise dimensions, and other drawing items which provides information for the CAD design to be manufactured by a third party and for other purposes.

Data Cache Persistence Servers (“DCPS”) 120 run software including, but not limited to, an operating system such as Ubuntu or other Linux variant and commercial or open-source software that allows other components of the System to very quickly store and retrieve data that is frequently accessed such as CAD model information and graphical “thumbnail” representations of CAD models and assemblies.

Document Management Web Servers (“DMWS”) 125 run software including, but not limited to, an operating system such as Ubuntu or other Linux variant and commercial or open-source software such as Jetty, Spring and other software written in the Java programming language. DMWS are Internet-facing (optionally through a network load balancer) servers that take network requests from clients in a REST protocol format and reply with information about the user's own CAD projects and projects that the user has the authorization to view. The user can also manipulate CAD projects (for example, but not limited to, create, delete, share, and rename) through communications with DMWS.

Asynchronous Message Broker Servers (“AMBS”) 130 run software including, but not limited to, an operating system such as Ubuntu or other Linux variant and commercial or open-source software such as RabbitMQ and other software written in the Java programming language. AMBS take messages sent from the DMWS, CEWS, and other Servers, and distribute those messages to asynchronous message consumer servers in specific geographies for processing based on the type of message. This allows for background processing and a high degree of scalability. Additional AMBS can be dynamically added or removed as system-wide processing needs demand.

Asynchronous Message Consumer Servers (“AMCS”) 135 may have lower physical resources (fewer or slower CPU, lower amounts of RAM) than other servers depending on the specific role that an AMCS is performing. AMCS run software including, but not limited to, an operating system such as Ubuntu or other Linux variant and commercial or open-source software such as Jetty, Spring and other software written in the Java programming language. An AMCS takes messages from an AMBS that are specific to a particular role and processes those messages. Example AMCS roles include, but are not limited to, processing graphical display data generated from the 3DGCS and creating thumbnail images, translating to and from industry standard and other CAD system file formats, and sending user notification emails when projects are shared. AMCS communicate via secure network protocols with data persistence servers and other external services. Additional AMCS can be dynamically added or removed as system-wide processing needs demand.

Data Persistence Servers (“DPS”) 140 run software including, but not limited to, an operating system such as Ubuntu or other Linux variant and commercial or open-source software like mongoDB to persist user login account information, user CAD projects, user, project, and system metrics, and other information saved on behalf of the user or the system.

Performance and Health Monitoring Servers (“PHMS”) 145 run software including, but not limited to, an operating system such as Ubuntu or other Linux variant and commercial or open-source software such as, but not limited to, logstash, elasticsearch, kibana and zabbix. PHMS continually collect performance and health data from other servers in the System via networking protocols. This data is transmitted via TCP and UDP networking protocols from all other servers running in the system, and is used to provide insight into user behavior, hardware and software failures and system performance.

Distributed Configuration Controller Servers (“DCCS”) 150 are preferably run in a clustered configuration in a Core data center. DCCS run software including, but not limited to, an operating system such as Ubuntu or other Linux variant and commercial or open-source software such as, but not limited to, zookeeper and puppet. DCCS provide a tree-like persistence mechanism where other servers, including DMWS, 2DDEWS, and CEWS, can read and write configuration keys and values and can listen for notifications if those keys or values (or their children in the tree) change. DCCS provides configuration to all of the other severs in the System. This allows for centralized management of configuration and ensures that configuration is consistent across servers and copies of each server. DCCS also provides service discovery. Each server in the System depends on services provided by other computers in the System.

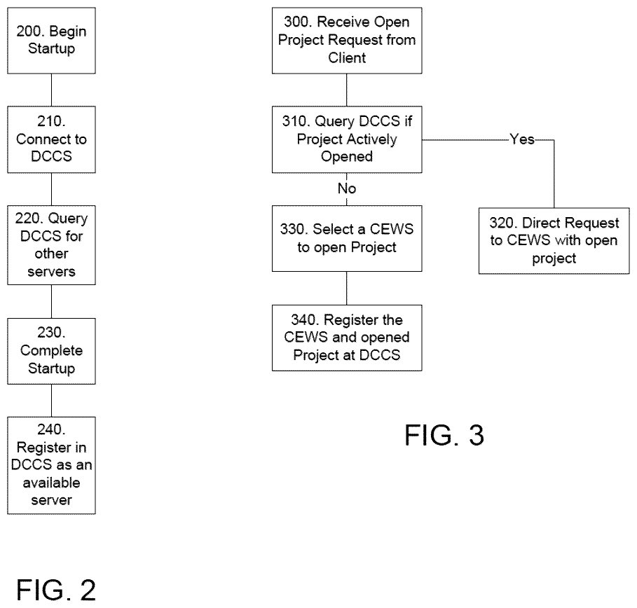

Referring also to FIG. 2, when a server (other than DCCS) is started 200, it connects 210 to and queries 220 the DCCS for the network location for the other needed services, and when the server is fully operational (startup complete) 230 it advertises 240 its own availability through DCCS. DCCS also provides CEWS locations for open projects in order to enable collaboration between CAD users.

Referring also to FIG. 3, when a user opens 300 a specific project, the DCCS checks 310 to see if that project is already opened on a specific CEWS. If so, the opening request (as well as further project editing actions) is directed 320 to the specific CEWS, ensuring all users actively working on the same project do so through the same CEWS. If not, the DCCS selects 330 a CEWS (such as based on geographic location, or current server loads, or other performance-focused criteria) to direct the request and open the project, and registers 340 in DCCS a listing of a project identifier associated with the specific selected CEWS.

Distributed Search Servers (“DSS”) 155 are preferably run in a clustered configuration in a Core data center. DSS run software including, but not limited to, an operating system such as Ubuntu or other Linux variant and commercial or open-source software such as elasticsearch. DSS provide both data indexing and a search mechanism for locating projects, parts, users, etc. from a query string.

Background Upgrade Servers (“BUS”) 160 are preferably run in a parallel configuration in a Core data center. BUS run software including, but not limited to, an operating system such as Ubuntu or other Linux variant, a web application written in a language such as Java, web application components such as Jetty and Spring; and other software. BUS are used in conjunction with 3DGCS at software upgrade time to iterate over all existing CAD projects, upgrade any structures in those projects so that they work correctly with the new software and verify that the upgrade process has not damaged the geometric integrity of the CAD projects.

Users connect through a client program running on a client device. Many different servers may interact, depending on the user action. Initial user connection and verification (secure identification) involves SCMS. Once connected and editing a project, a network websocket connection is established between the client and a CEWS for the opened project. The CEWS manages user editing and view change actions, while asynchronously sending requests to other servers as needed.

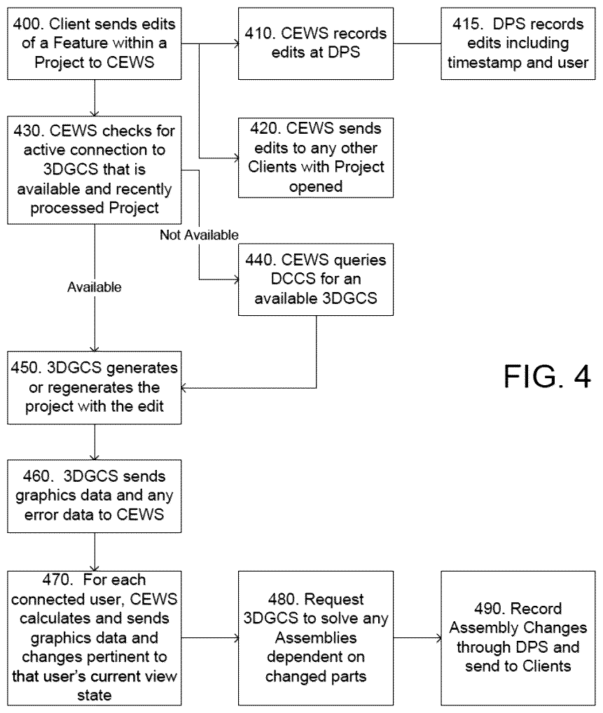

Referring also to FIG. 4, in an editing example, the client sends 400 the CEWS an editing message with an identification of a feature being edited, and details about a change. The CEWS asks 410 the DPS to record the edit as an increment on a project branch the user is working on, including 415 a timestamp and user identification. If there have been too many increments since the last full (non-incremental) record, the CEWS asks the DPS to write a full record (as an optimization). The CEWS also sends 420 the edit information to all clients connected to the project (so that they can appropriately update indications about the edit). The CEWS checks 430 if it is connected to a 3DGCS that is available and recently regenerated the part studio in a similar state. If not, the CEWS asks 440 the DCCS for a 3DGCS server and asks it to launch a new 3DGCS process. With a 3DGCS appropriately available, the CEWS sends the change to the 3DGCS (and more project data if needed by a newly available 3DGCS) and generates or regenerates 450 a model based on the changes. The 3DGCS sends 460 a tessellation increment (triangles, polylines, etc.), error state, and other graphics data about the features it regenerated back to the CEWS. For each client connected to the project, the CEWS sends 470 back the tessellation and other increments. Because the clients may be in different states, the increments they need may be different and the CEWS computes the appropriate ones for current display on each connected client. If there are, for example, assemblies in the same project referencing a changed part, the CEWS updates these assemblies. This may involve asking 480 3DGCS to solve the assemblies and DPS to record 490 the changes. The CEWS sends changes to the assemblies to all clients connected to the assemblies.

Client

Users interact with the system through one or more clients, each running on a client device 170. Different client programs are designed to allow users to work on CAD projects from different client devices. For example, a user may start a CAD project in a web browser on a desktop computer at work, continue updating the project on the road using a mobile phone, and finish the project on a computer tablet at home. This enables system access and operation from any computing device and from anywhere there is an Internet connection.

Client programs can generally be classified as either web clients designed to work within a browser through HTML, CSS, JavaScript, and WebGL, or native applications designed for specific platforms such as mobile phones, computer tablets, and other internet appliances and with operating systems such as, but not limited to, iOS and Android. Native applications may implement communications to servers matching the communications performed by web clients, while optimizing appearance and/or interactivity (such as user input and control) specific to an individual platform or line of computing devices.

Web Client

Web clients run inside standard browsers such as, but not limited to, Chrome, Firefox, Safari, Opera, and Internet Explorer, using HTML, CSS, JavaScript, and WebGL. This allows operation without any required installation or plug-in on the client device operating the web client. The web client is light weight and may work with a large number of devices, including, but not limited to, computers, Chromebooks, televisions, gaming consoles, and other Internet appliances. Web clients work with any WebGL compatible browser, such as, but not limited to, Safari, FireFox, and Chrome, running on any computing device with WebGL compatible graphics hardware.

Apps

Native applications (Apps) are built for dedicated system platforms, such as, but not limited to, Apple iOS, Android, and Mac OS X. Apps require download and installation, so in many cases may be less desirable than web clients, but can take advantage of platform-specific features. These apps can be installed on devices such as, but not limited to, computers, tablets, smart phones and other wearable devices like watches and google glass. Apps are designed to provide the best experience possible for a given platform, for example, by optimizing user interaction for the size and orientation of the device's display area, and for unique capabilities such as but not limited to touch interaction and accelerometers.

For example, the iOS app operates on Apple mobile devices including iPhone and iPad. This app utilizes dedicated platform features, including touch gestures, Wi-Fi and cellular networks, and device notifications. For performance and graphics capabilities, the iOS app requires iOS 7 or above.

As another example, the Android app operates on mobile devices running an Android operating system, and, similar to the iOS app, utilizes dedicated platform features including touch gesture control and device notifications. The Android app works with any Android device supporting KitKat or LollyPop or above.

Specific Process Details

Overview

The multi-user cloud-based 3D CAD system presents an editing user interface (UI) for users to design, modify, and share structures. For each user, the system begins with authentication, and then presents various projects to the user. Each project is for the design of one or more structures, or assemblies, which is made up of a collection of instances of parts and sub-assemblies. Each project is made up of multiple data units, referred to herein as tabs, representing the assembly, parts, and other data desired as part of the project. A history of actions, or persistent transaction history, is associated with each project, and the histories may be branched to allow multiple workspaces (and different end assemblies) within the same project. Projects may be shared with multiple users, allowing concurrent editing to occur.

Authentication

A user begins use through a client device. The figures and examples discussed herein generally refer to the web client with browser access such as through a desktop or laptop computer, but the same concepts, operations, and interactions with the servers and user interfaces apply to dedicated apps on any client device, such as a smart phone or tablet, with input controls changed to match those used with the specific device.

A first step may include authentication of the user through the client. A preferred embodiment is through input and verification of a username and password, but alternative forms of secure authentication (for example, but not limited to, two stage authentication or biometric authentication) may be used. A web client may provide an authentication page from the DMWS, while a dedicated app may generate an authentication page (or retain authentication information). The authentication information may pass to the SCMS, and after authentication the DMWS, in conjunction with the DPS and DCPS, may present an overview page for display by the client (or overview information for display through a dedicated app). Alternatively, this may be configured to be a different initial view, such as to present the last view of the user at the most recent prior session.

Projects

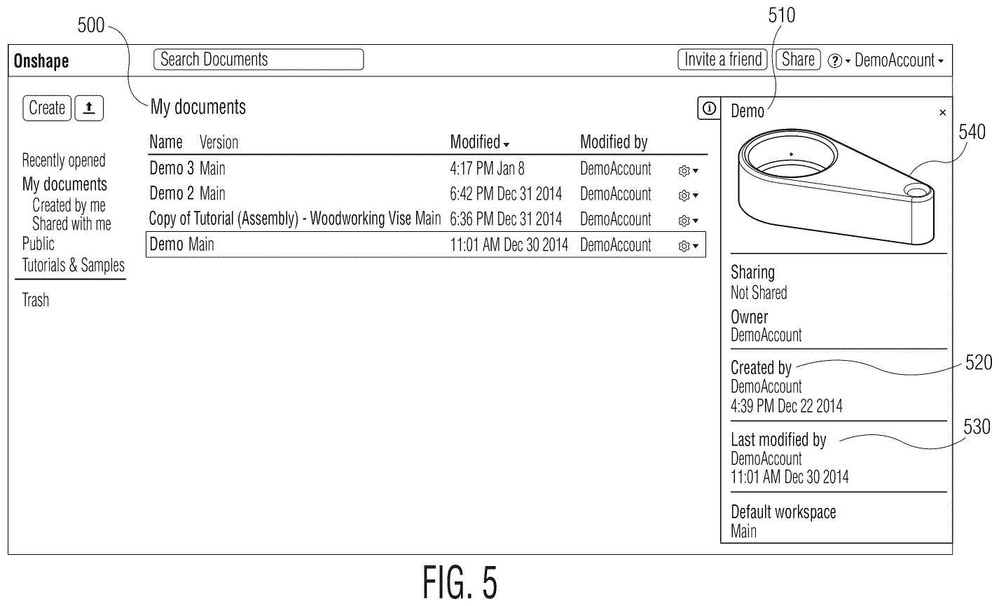

Referring to FIG. 5, the overview presents various management options as well as access to projects. Within this system, each assembly is retained with all related data (subassemblies, part studios defining parts, and other tabs) in a single compound document (as later detailed). Thus, the interface shown in FIG. 5 refers to projects as documents (notably, “My Documents” 500).

Within the overview, profile management options may allow setting basic information, such as name, company, contact information, and account password. Additionally, default settings may be configured, such as units to use for length, size, or angles. Default settings will apply unless specifically configured at a lower level (such as at a project, workspace, or tab level). The overview may present information about one or more projects, such as name 510, creator 520, last modification 530, and a small or thumbnail visualization 540 may be presented, along with global account information such as last access, total storage use, and any account restrictions such as storage or computational time remaining.

Projects may be listed in various configurable views, such as recently accessed projects, projects created by the account user, projects shared with the account user, and public projects. Each project may provide options to view versions, history, control sharing, delete the project, or open the project for editing.

Project Structure

Each project is able to store an entire and unlimited-size collection of CAD parts, assemblies, drawings, and arbitrary other CAD and non-CAD data. This collection is stored as a Compound Document by DPS, and it may be shared and/or versioned. As a compound document, it is stored as a single data structure which is actually made up of any number of internal components referred to as tabs, which traditionally would be stored as separate files on a computer disk or storage unit.

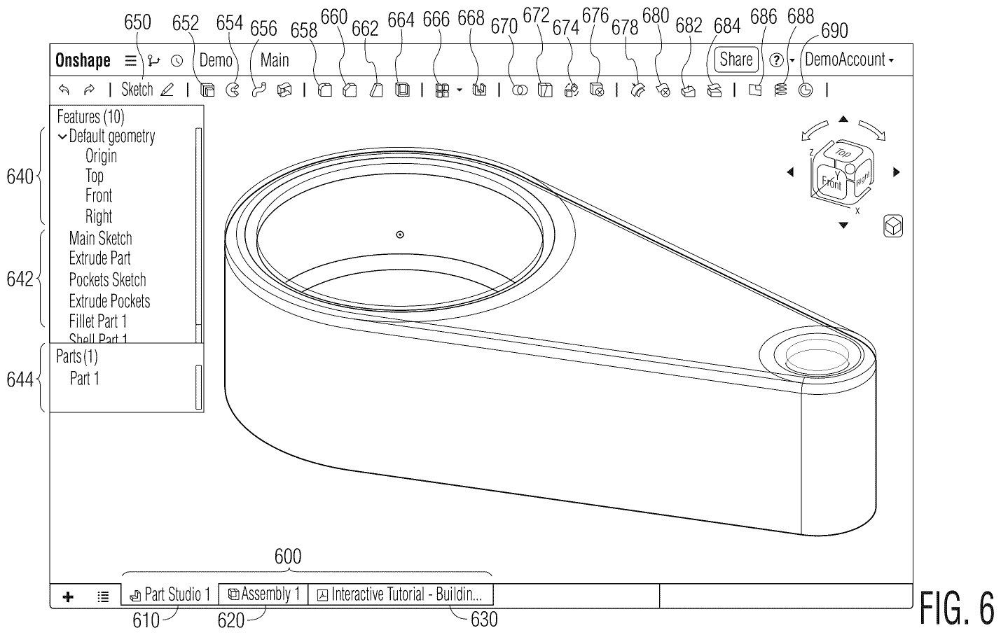

Referring to FIG. 6, when viewing a specific project, the internal components are accessible as separate individual tabs 600 accessing individual panes within a project workspace, with each internal component having its own tab. This allows bundling CAD data (such as parts, drawings, and assemblies) as well as non-CAD data (for example, but not limited to, PDF files, word processing files, and spreadsheet files) into a single project. A Part Studio tab 610 displays and interface that can be used to define parts. An Assembly tab 620 displays an interface that can used to define and/or modify a hierarchical structure of part and sub-assembly instances which combine into an Assembly. Additional tabs 630 can be used to display non-CAD data, such a tutorial.

Management and sharing can be simplified, as links between CAD objects, such as an assembly referencing a part, can be references internal to the document and not dependent on any file system naming or structure. Users sharing an entire project share access to that single compound document, ensuring all shared users have the same environment with correct references. File system actions, such as users moving or renaming files or folders, do not risk impacting the project due to the single compound document. Versioning (and change tracking) is done at a project level and automatically applies (and is tracked) across all internal components of the project. This avoids potential conflicts of incorrect versions of individual files and simplifies management by avoiding the need to separately track changes and versions of every file involved. This also guarantees that every user accessing a project has the correct matching versions of all elements/tabs, as the tabs are all stored and versioned together in one Compound Document. For use with other systems, or selective distribution, individual tabs may be downloaded as individual files, with such download becoming separate and unlinked from the entire project. Various export or translation options are available for CAD-format tabs, and non-native CAD files that are stored in tabs of the project are available to download to recreate exact copies of the original files.

References may also cross projects. For example, an assembly in one project may reference a part defined in another project. All cross-project references reference only reference data objects that exist within versions. Because versions are immutable, changes to the reference project can never inadvertently change the referencing project. The user receives notifications when new versions become available and may then choose to update or not update.

Client user interface controls may allow uploading, downloading, and translating CAD Data. The system allows users to upload and download CAD files into project tabs as Part Studios, Assemblies or as exact file copies, to translate CAD data, from one type to another, and to export as CAD files.

Upload allows uploading any type of file from a location in local storage, network storage, or cloud services such as Dropbox or Google Drive, that is addressable by the client device, into the system, stored within a project by the DPS. Uploaded files may be stored into an existing project, or into a newly created project. How the system handles an upload depends upon where the upload was initiated. If initiated from the Projects overview, the upload creates a new Project with appropriate tabs.

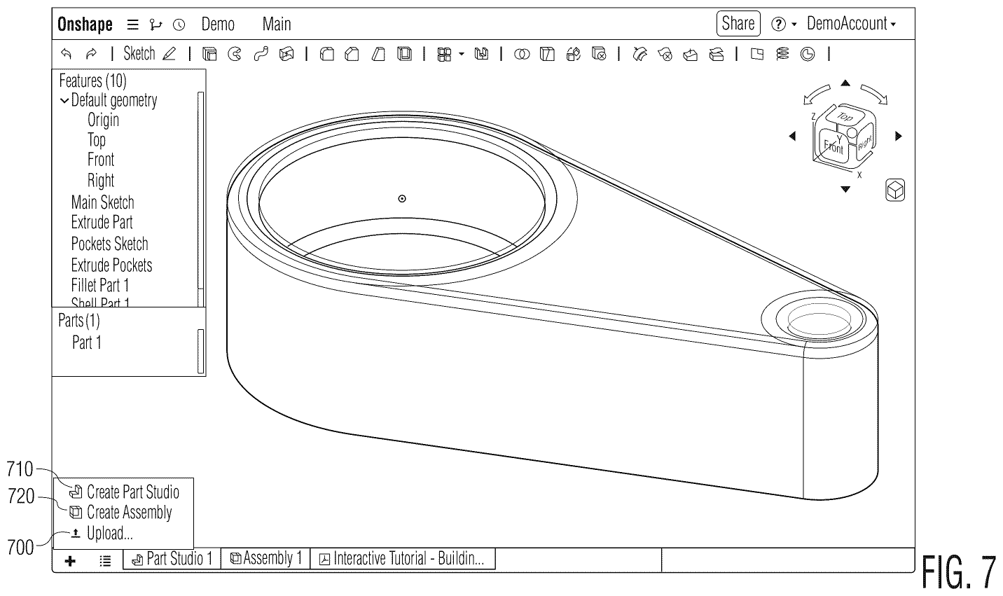

Referring to FIG. 7, if initiated from inside a Project, or to a specific Project, usually a new tab specific to the type of file upload is created within the Project. Every file uploaded 700 into a project usually becomes its own tab, named with the original file name. If the file is a CAD file, appropriate Part Studio, Drawing and/or Assembly tabs for that CAD file may also be created via CAD data translation by the system. Any type of file can be uploaded into the system, although file types not understood by the system may lack functionality or display capability within the client. In addition to uploading existing files, new and blank part studio 710 and assembly 720 tabs may be created.

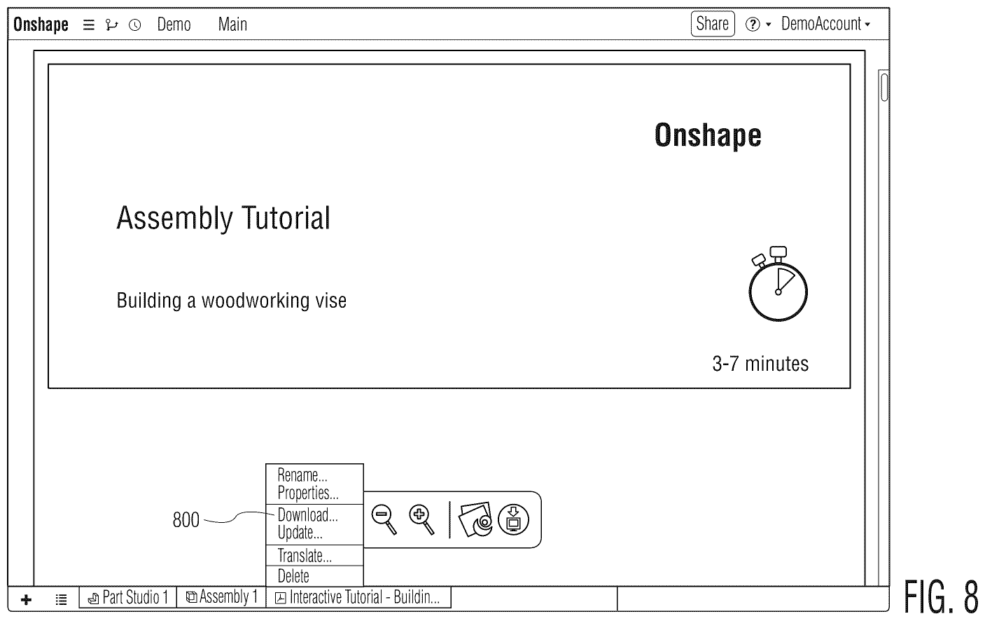

Referring to FIG. 8, downloads 800 can be initiated through context menus of tabs within projects and are available for any tab that can be represented as a file. A download copies any file that was previously uploaded into a project back out in its current file format to a storage destination addressable by the client device.

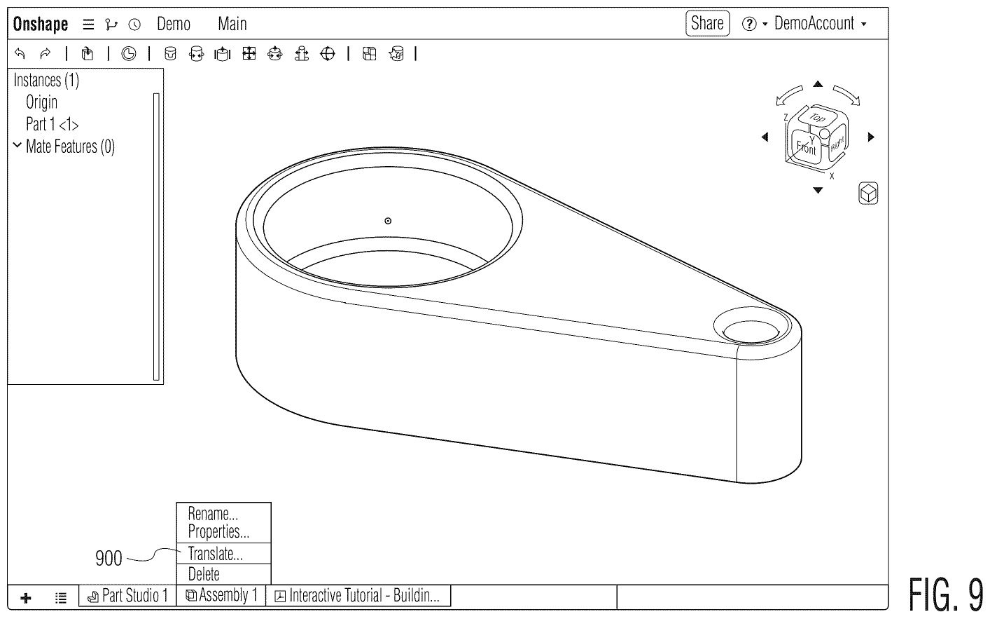

Referring to FIG. 9, translate 900 allows converting a part studio, drawing or assembly file into a different format, and displays as a new tab within a project. Translate may apply to any default tabs (Part Studios or Assemblies) as well as any uploaded CAD files. Some example translatable formats include, but are not limited to, Parasolid, ACIS, STEP, IGES, CATIA v5, SolidWorks, Inventor, Pro/ENGINEER, CREO, and JT. When a CAD file is uploaded as a new Project, processing options are automatically presented. When uploaded into an existing project, a translate option may be selected to automate options. When translating a CAD file, options are presented to select from vendor-specific or generic CAD formats, and to specify options such as source orientation. Some three dimensional CAD systems use a “Y Axis Up” coordination system, while others use a “Z Axis Up” system. Additionally, if the file is an assembly, or contains an assembly, another presented option is to translate the file as only a Part Studio, which is selected through a Flatten option. With the Flatten option selected, the assembly is flattened to a set of parts in a Part Studio. Translation and flattening are performed through communication between the client and DMWS, DPS, AMCS, AMBS, and CEWS. Non-native CAD files in a project may also be translated into a native CAD format. This creates a new tab for the translated CAD file and retains the original non-native CAD file as part of the project (which may be desired for future download in the original format version).

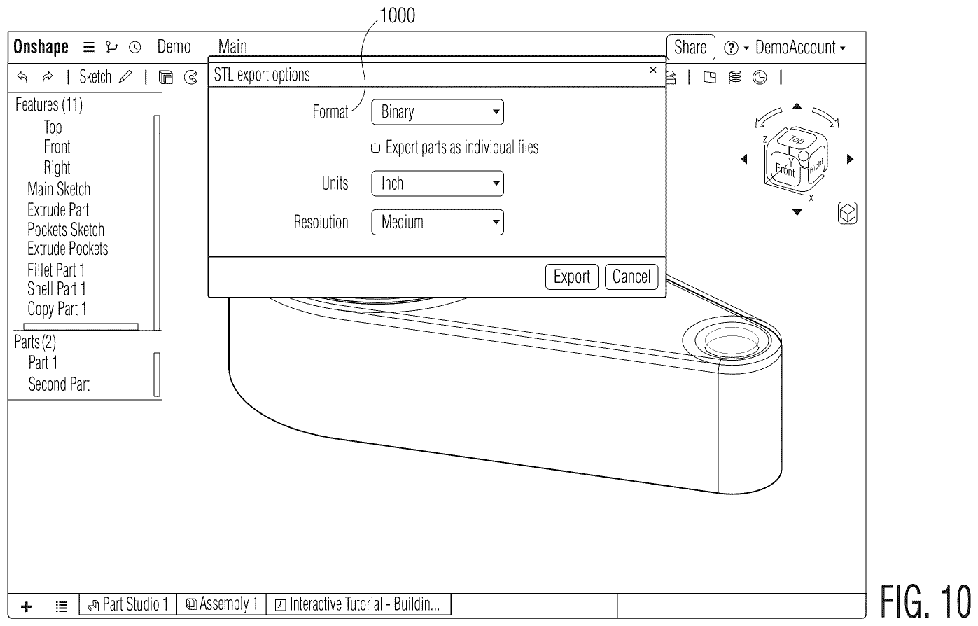

Referring to FIG. 10, users have the option of exporting either an entire Part Studio or individual parts within a Part Studio to an STL or other type of file 1000. Export translates a Part Studio (or individual part) to a format, for example STL format, and downloads it to a storage location addressable by the client device.

Editing a Project

Once a project is opened by a client, each tab represents a file within the single compound document of the project. Opening an existing project opens tabs for all files within that project. Creating (and opening) a new project starts the project with a default workspace and default tabs, for example a Part Studio and an Assembly. The tabs may be rearranged (ordered positioning), and this action applies to the workspace (so would also be applied to any other users collaborating on the same workspace). Which tab is currently active, and any positioning/scrolling of the workspace, are user-specific and non-persistent. Therefore, each user collaborating on a project workspace has their own active tab and their own tab scroll state. Options for each individual tab, accessible through the user interface, may include renaming the tab, viewing and editing tab properties (such as, but not limited to, description; part number; revision; state of a part), duplicate, copy to clipboard, export to STL, translate, and delete. Duplicate creates a new tab with an exact copy of the duplicated tab, with each of the duplicate tabs being independent. Thus, changes in the copy do not impact the original tab. Translate similarly creates a translated copy in a new tab, leaving the original formatting in the previously existing tab.

A project menu, also accessible through the user interface, allows project-wide options such as to rename the project, copy the current workspace, view or change properties (such as default units), print, access versions and/or persistent transaction history, and undo or redo actions.

Metadata

The system allows users to create and edit metadata for parts, Part Studios, Assemblies, Drawings and foreign data (non-CAD tabs) in order to support various design processes.

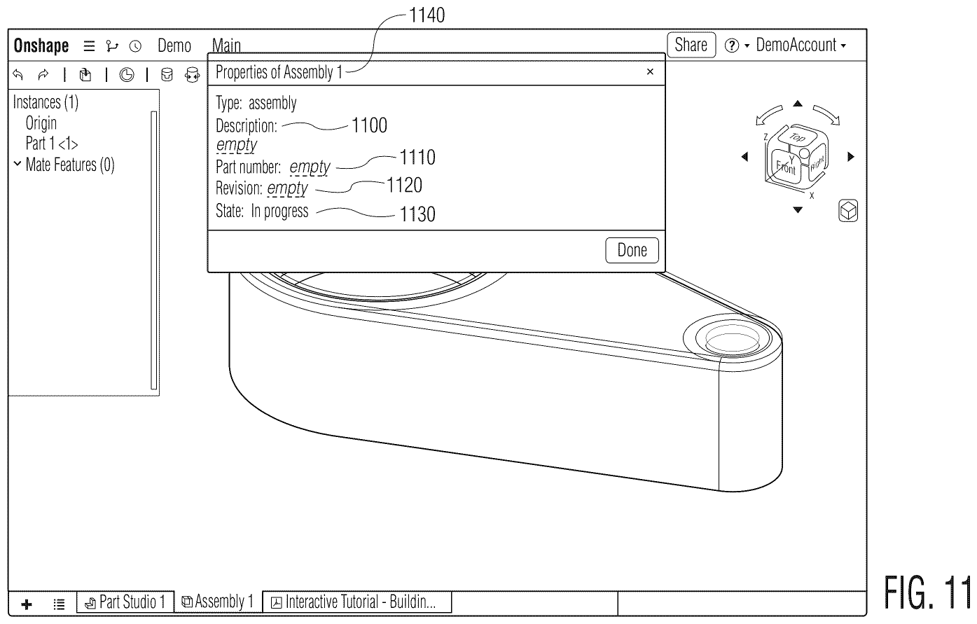

Referring to FIG. 11, metadata may include a description 1100, part number 1110, revision 1120, and state 1130 (in progress, pending, released, or obsolete). Metadata is defined and edited through the Properties dialogs 1140 found on various context menus. Parts metadata may be accessed and edited through a context menu on a part listed within a Part Studio feature list. Part Studio metadata, assembly metadata, and foreign data file metadata may be accessed and edited through context menus on individual tabs within a project. Additionally, all types of metadata may be accessed and edited through a properties dialog for a version or workspace accessed through a Version Manager.

Workspace

The user interface workspace for an active project includes a menu bar or user interface control button area, tabs for all files in the project, a graphics area for the active tab, and a feature list. The graphics area displays the active Part Studio, Assembly, or other tab. The feature list has different data depending on the active tab. If a part studio is active, the feature list contains a parametric history of work, and a Rollback bar to view work at a certain point in the parametric history. If an assembly is active, the feature list contains the Assembly tree structure, Mates, Groups, and Mate Connectors.

User interface display and interaction with the workspace may vary depending on the client device and input/output capabilities. Typically, selection is done via click (or touch), and may be added to by additional clicks. Click-and-drag or touch-and-drag also enables selection of multiple entities. Different group selections may be possible. For example, the direction of drag (and as indicated by a specific color of the selection box) may toggle between selecting all entities entirely within the box, and selecting all entities touched by the box. Additionally, clicking (or touching) something already selected deselects it.

Dialog controls are used extensively, and many different aspects of CAD design have different options to configure. Dialogs are accessed through menu selection or right-click in feature list. UI design of the dialogs may identify required selections through highlighting (and selection may be made through the graphic area or feature list).

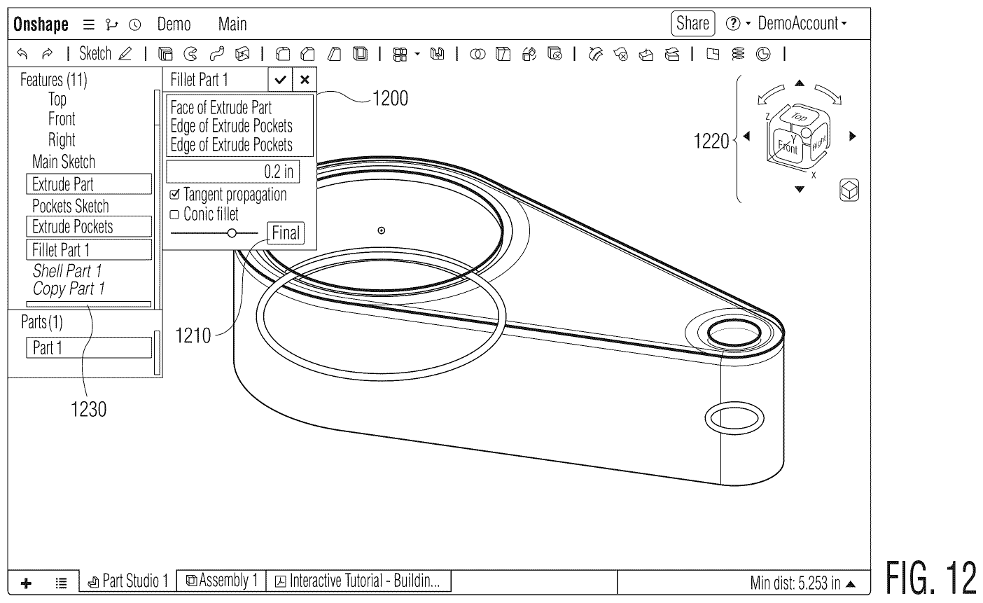

Referring to FIG. 12, configurable properties in dialogs 1200 may include different aspects, such as units input as part of numeric inputs (which may override default or project unit settings), number input in the form of mathematical expressions (PEMDAS or trigonometric), or global variables and equations. Dialogs may also include a preview slider as detailed in U.S. Pat. No. 9,741,157 “Previewing Changes On A Geometric Design”, which is fully incorporated by reference herein. When a user edits a feature, by default the model displayed is rolled back to its state when that feature was created, hiding all later features (with features sequentially applied from top-to-bottom as listed in the feature list). The Final button 1210 displays the final result with later features applied while the user is still editing the feature. If editing the last feature, the user interface does not need to display the Final button, as there are no later features to apply.

Graphic Area Controls

Within the graphic area, mouse or touch control may rotate (3D), pan (2D), and zoom the active view. A view cube 1220 may be also displayed, with user interface interaction with the view cube adjusting the active graphic area view. For example, arrows around the cube may rotate the view in any of six directions, selecting a planar face of the view cube may change orientation to the plane, and a dot or other indicator on the cube may auto adjust to an isometric view. A view cube menu may allow further options, such as isometric, dimetric, or trimetric; specific section views; zoom to fit; toggling perspective; controlling shading and edges; and adjusting translucency (transparency may also be set on a per-part basis by changing appearance of selected individual parts).

Error Conditions

As part of dialogs and general user interface design, visible error indicators are displayed in colored text. The most common errors may be determined by 3DGCS or CEWS while editing a part or assembly. For example, when there is a problem with a feature, a user may see that feature in orange text in the Feature list. Hovering over or selecting orange text in the Feature list may further display a summary of the issue. With a dialog active, the dialog title may be colored orange to indicate error. Within the dialog, orange text may identify entities previously input into a dialog box which have been deleted or may identify error conditions preventing application/operation of the dialog box. When the problem lies in a single field, like an invalid entry in a numeric field, that field may be outlined in red. Similar error indicators may extend to sketching. Color may be used to indicate the constraint status of sketch entities, for example, blue means under-defined, black means well defined, and red means over-defined (over-constrained). With constraints, standard coloring (such as a gray square with a black icon inside) may indicate no error, while color indicators (such as a red square with a white icon) may indicate a problem with a constraint. If a more general system error occurs, a notification may appear in a bubble at the top of the user interface window.

Sketching

Sketching is an editing mode for editing geometric shapes within a specific plane. The results of sketches are features which are used to create parts for an assembly. Sketching is entered while editing parts, and it can be used to create geometric shapes which become parts or modify geometric shapes of existing parts. Some options are the same whether sketching or editing parts and features outside of sketch mode, but sketch mode also allows some sketch-only options.

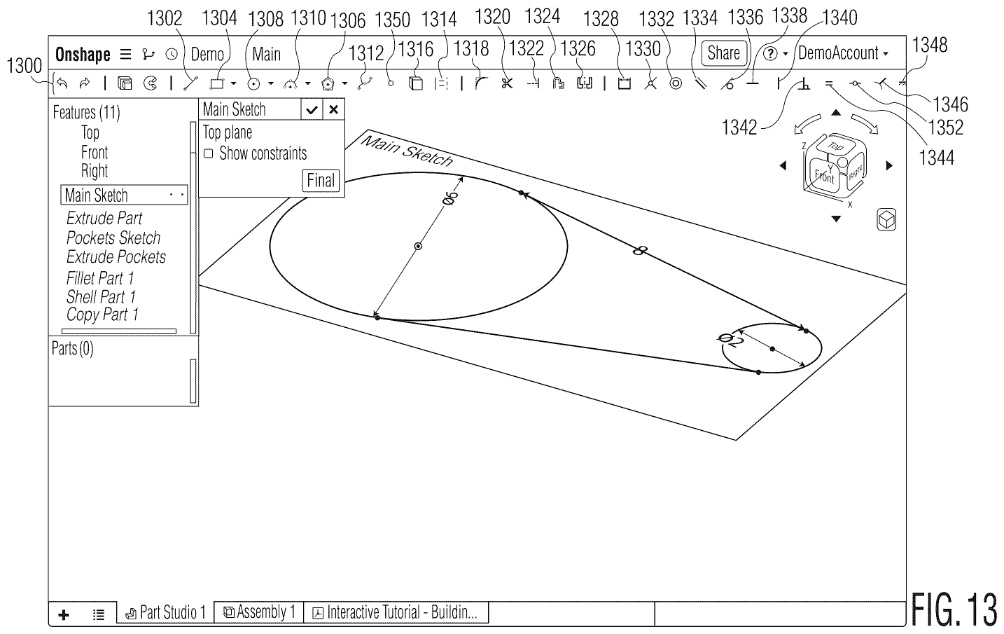

Referring to FIG. 13, a sketch toolbar 1300 with such options becomes active when creating a new sketch, editing a sketch, or when selecting a sketch option. In all cases, a specific plane is required to orient the view for the sketch. The sketch toolbar contains tools to begin or edit a 2D sketch which is used to create or modify a 3D feature or part.

Some of the sketch options include tools for basic geometric designs. For example, lines 1302, rectangles 1304, polygons 1306, circles 1308, arcs 1310, and splines (multi-point curves) 1312 may be created or edited within the sketch plane. Basic geometry constructs, such as lines, rectangles, and circles, may be created by user interface interactions directly in the graphics area, such as by selection or drag actions to set any endpoints, vertices, or curve control points. More complex tools may also have dialogs to set any required input or configuration (such as number of sides for a polygon). Construction 1314 allows creating new geometric constructions or converting existing entities into a geometric construction.

Additional tools may modify existing geometries. For example, use 1316 or convert may project (or convert) one or more edges of parts onto the active sketch plane. Fillet 1318 may create fillets (rounds) along one or more lines, arcs, and splines. Trim 1320 may restrict a curve extension, and extend 1322 may stretch a line or arc, to a first intersecting point or bounding geometry. Offset 1324 may shift a curve or loop a specified distance and direction from the original. Mirror 1326 may copy one or more entities in the sketch plane and mirror them across a selected line. Dimension 1328 may add horizontal, vertical, shortest distance, angular, or radial dimensions to sketch geometry.

Additional options allow constraints between multiple geometric entities, thereby controlling shape and/or positioning. For example, coincident 1330 makes two or more entities (lines, curves, or points) coincident. Concentric 1332 makes two or more circles or arcs share a common center point. Parallel 1334 makes two or more lines parallel. Tangent 1336 forms a tangent relation between two or more curves. Horizontal 1338 makes one or more lines, or sets of points, horizontal within the sketch plane. Vertical 1340 makes one or more lines, or sets of points, vertical within the sketch plane. Perpendicular 1342 forms a right angle between two lines. Equal 1344 makes two or more curves of the same type equal in size. Normal 1346 positions a line to be on a normal to a curve. Fix 1348 grounds a sketch entity on the sketch plane.

To aid in positioning and constraints, point 1350 may create points anywhere on a sketch entity, allowing constraints to be fixed to such point. For positioning control, midpoint 1352 constrains a point to the midpoint of a line or arc. Some of the tool options create points or constraints by default. For example, when fillet rounds multiple lines, arcs, or splines, it adds (or retains) a coincident constraint to keep the lines, arcs, or splines together. Similarly, common points are automatically created with geometric entities (such as vertices, ends of lines, and centers). These points may be used in constraining geometric entities. Constraints are only displayable and modifiable while in sketch mode and may be displayed with icons and colors through the user interface.

Error conditions with constraints can also be displayed, for example, blue color may indicate under-constrained (more constraints possible on a geometric entity), black color may indicate fully constrained (no errors, but no alterations possible due to the current constraints on a geometric entity), and red color may indicate over-constrained (more constraints exist than can be resolved into a valid geometric entity).

Inferencing

When sketching, a user often wants geometry to be related to other geometry in a persistent way. Such relationships can be added after the geometry is created. However, it is much more efficient for the user to create such relationships dynamically, while creating the geometry. Such dynamic constraints are often called inferences or snaps because the visual appearance is that the geometry being created visually snaps to existing geometry.

While sketching, inferencing occurs to guess at likely constraints, display indication of such guess, and automatically create the constraints if appropriate based on user input. One example of this is horizontal or vertical alignment—when creating or moving an entity, such as a line, if approximately horizontal or linear to another entity, such as the point of origin, positioning can automatically be made in vertical or horizontal alignment. This automatic adjustment may be triggered by user action, such as by holding a user interface element in one spot for a period of time to indicate alignment is desired, disabled by user action, such as holding a modifier to prevent any automatic inferencing, and visually indicated within the interface, such as displaying dashed lines to indicate alignment and inferenced constraint.

To perform the needed inferencing, the system performs all the complex intersections and other geometric calculations on the 3DGCS, freeing the client from such work. While inferencing is being calculated server-side, the client allows sketching to continue, even while waiting for any server-side results. To incorporate 3DGCS calculated inferences and geometric changes seamlessly at the client, WebGL is used to process inferences. This results in optimizations both client-side and server-side while mitigating the communication time by providing a continuous user experience on the client while the server is working.

To start inferencing, the client sends a request to calculate inference targets. While waiting for the data from the server (3DGCS via CEWS), the client provides user interface functionality to the user, enabling continuing geometric edits but not displaying any inferencing. When 3DGCS computes inference targets, they are returned to the client and rendered to an off-screen graphical buffer in WebGL. The inferences are returned as an object containing an index to identify the individual inference, an identity of an inference source (for example, a model edge), one or more types of constraints applicable to the inference, and an inference zone which provides a geometrical description of an area that will snap to the inference (for example, a point or a line). Client-side comparison between the inference zones of inference targets in the WebGL buffer and user interface interaction may determine which, if any, inferences should be displayed to the user. Often the server responds before the user has reached the location at which he wishes to place the geometry, resulting in instant inferencing, but even when waiting for server response the client-side user experience is seamless.

When a user begins sketching, the client asks CEWS for any inferences specific to the entity being drawn. Regardless of server response, the client continues to update the displayed sketch based on user input control (e.g., mouse control). Before server response, such client updates occur without performing any snapping (no inferences yet to snap to). When CEWS returns inference information, the client checks the inference zones to find any nearby inference, visually snaps geometries to matching inferences, and displays to the user that a snap has been successful. When geometry has snapped to an inference, the system adds corresponding constraint(s) from the inference to the sketch. This inferencing model applies to constraints inferred between any geometric operation or creation, with point creation illustrated as the clearest example to follow.

Table 1 below outlines the client and server interactions for the case of creating a point.

TABLE 1

| Client | CEWS & 3DGCS |
|---|---|
| Receive user command to start point | |
| creation | |
| To server: Start inferencing (type: | |
| point) | |
| Repeatedly: | Calculate inferences to sketch and |
| Process user input, such as moving | model geometry and intersect non- |
| the mouse | point inferences to produce |
| | compound inferences |
| | To client: Send calculated |
| | inference |
| Receive inference and updated | |
| WebGL inference buffer | |
| Repeatedly: | |
| Process user input, such as moving | |
| the mouse. | |
| Interrogate the WebGL inference | |
| buffer. | |
| If an inference is found adjust the | |
| displayed position and display cues, | |
| indicating which inference was found | |
| User places the point | |
| To server: Create a point at a | |
| location. If a snap was in effect | |
| send the inference back to the | |
| server. | |
| | Received point creation command |
| | from client: Create the point |
| | If an inference was also supplied |
| | then use the data within the |
| | inference to create the constraint |

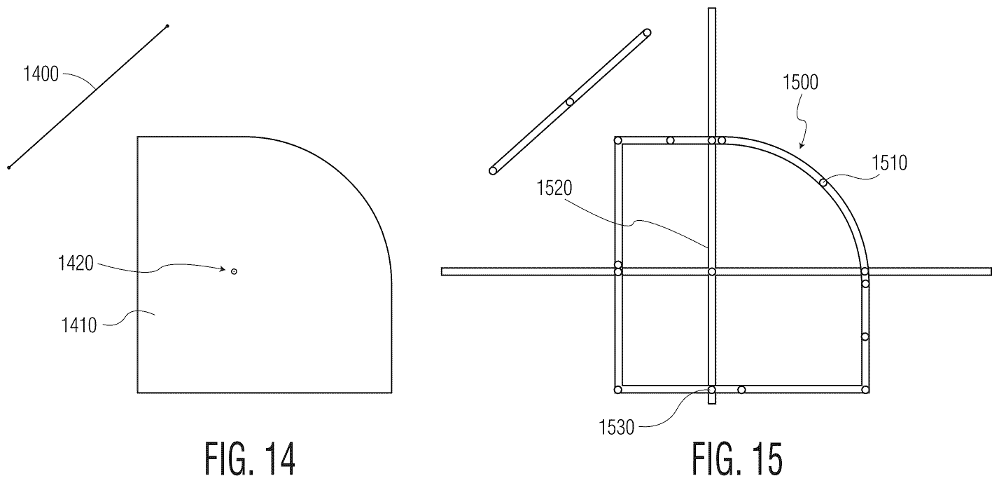

Referring to FIG. 14, a sketch may appear to a user with a model face 1410 and already drawn line 1400. Also visible to the user is a global model origin 1420. When the user enters a “point” command, the client asks the CEWS to generate a list of inferences. This is needed as the client doesn't have all the information needed to generate inference data. Sending all of that information to the client and performing the mathematical calculations on the client requires time and computational power likely to introduce unacceptably large delays in the response of the client.

While the server is generating the inference, the client processes user input. When the client receives the response from the server, it processes that information to generate a selection buffer in WebGL. The use of WebGL to perform inference picking is significantly more efficient than iterating through all of the inference data and performing mathematical operations to find a match because graphics hardware is very good at processing a lot of data in parallel.

Referring to FIG. 15, a visualization of the geometry is drawn into the WebGL inference buffer. Four inferences are highlighted in the figure, including coincident to edge 1500, midpoint of edge 1510, and vertical to origin 1520. In addition, it is often useful to snap to compound inferences. Compound inference 1530 is a combination of a coincident inference to the edge and a vertical inference to the origin. By separating inference calculation from the client, and continuing client operation during inference calculation, the server is able to calculate the (many) necessary intersections without affecting the client experience. For every inference in the inference buffer, the client decides a snap tolerance and renders a stripe or dot that incorporates this tolerance. Once this buffer is drawn it can be sampled at the position of interest.

If an inference is found at a position indicated by the user, the client uses the inference data to determine how to appropriately notify the user of the snap (e.g., by highlighting the source of the inference and displaying an indicator showing the type of inference) and modifies the position of the point to conform to the snap.

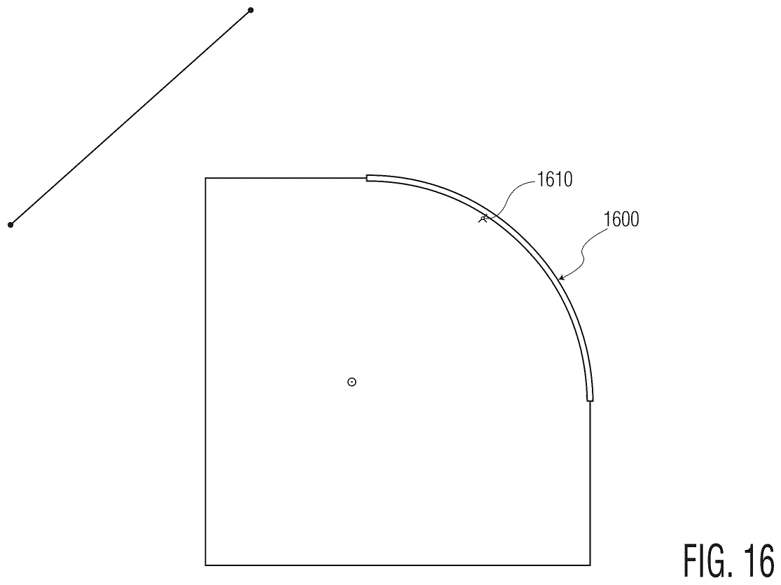

Referring to FIG. 16, a newly created point is snapped to the coincident inference and indicated to the user through highlighting the inference source 1600 and display coincidence indicator 1610. When the user places the point, the client asks the CEWS to create the point. If the client is currently snapping to an inference, the client also passes that inference to the server. When the CEWS receives the data, it creates the point and any constraints related to the passed inferences.

This communication between client and CEWS is done as a conversation. The client asks for the most immediately useful inferences. As the user mouses over or otherwise moves model geometry or view of the geometry, the client asks for additional inferences related to that geometry. This conversation minimizes the number of calculations required without adversely affecting the user experience. By updating the WebGL inference buffer asynchronously on the server only when necessary (for example when model geometry is changed) and much less frequently than inferences occur (which usually happen locally entirely on the client), the user experience is optimized.

Predictive Drag

As with inferencing, if the client waits for server calculations while modifying any geometric model, noticeable delays may impact user experience. To avoid such delays, the client may implement a predictive drag, which estimates resulting geometries as user interface movements (dragging geometries via a mouse or touch control) are made. To enable such estimation, data is created by the 3DGCS and CEWS, which can be used as drag information by the client. This drag information consists of two parts: data that indicates certain ways in which the geometry is constrained to move (degrees of freedom) and approximate derivatives of a solution function. The 3DGCS runs a complete solution function when solving geometries after client changes, but this includes complex calculations beyond the scope of the client. The derivative functions provide a less complex approximation capable of being efficiently run by the client. The client, in turn, applies the drag information constraints and derivate functions to approximate sketch solutions, thereby updating the sketch in real time as users geometrically drag elements in the sketch. Asynchronous communications between the client and CEWS allow updating the sketch shown on the client as it is solved server-side and also updating drag information, which accounts for any made changes.

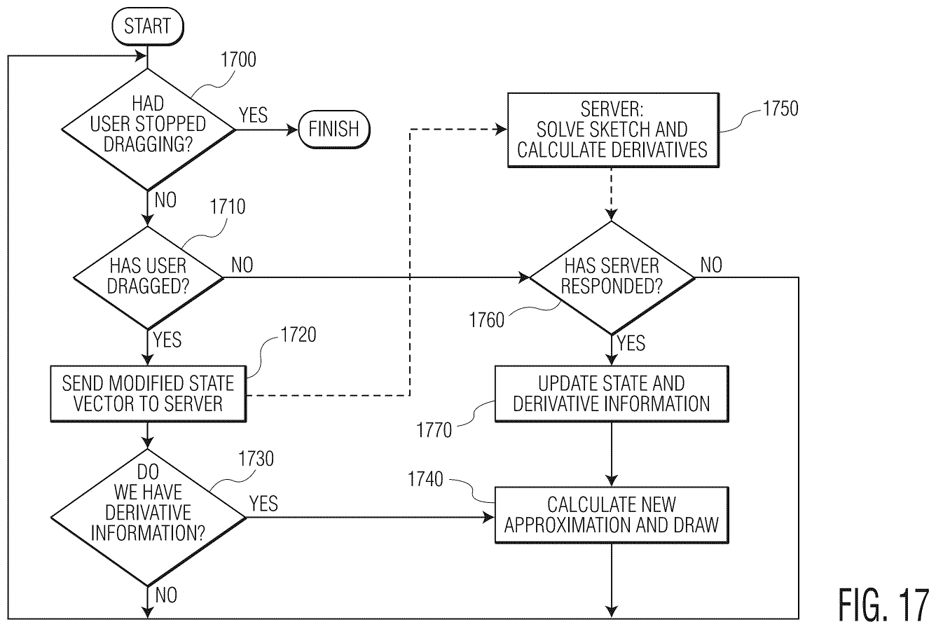

Referring to FIG. 17, a flowchart illustrates the logic and client-server interaction as a user drags geometry in a sketch. If a user is not dragging 1700, then no new dragging update requests are made to the server. When a user makes a dragging action 1710 in the sketch, the client sends 1720 a modified state vector to the server. If the client has derivate functions 1730, it locally calculates and updates 1740 the graphical display using the derivative functions. The server, upon receipt of a modified state vector, solves 1750 the sketch and also calculates new derivative functions based on the newly solved sketch. When the new sketch and derivative functions are received 1760 by the client, the locally tracked state and derivative functions are updated 1770 and the current display redrawn 1740 with the server-solved sketch.

When solving the geometries of a sketch, through user dragging or other geometric changes, a solver recalculates the positions of all geometry to satisfy any constraints configured within a sketch. Typically, the set of constraints is complex (and grow more complex and involved the larger and more complicated the sketch), and the calculations can take noticeable time to complete even when solved on a high-powered server. Each geometry is represented by a vector of numbers. The vectors for a sketch can be concatenated into a single state vector, which can be denoted as x=[x₁ x₂, . . . , xₙ], a vector of n numbers. The solver can be represented as a function f that produces a new vector x that satisfies the constraints.

The client, given this vector x, displays the solved sketch geometry to the user. A simple algorithm would involve the client making changes to x, sending the changes to the server, waiting for a response from the server with a new x, and updating the display to show the solved sketch geometry of the new x. With any kind of complexity in solving for the new x, the client appears sluggish with time waiting for the update. To avoid such waiting behavior, the 3DGCS uses finite differences to calculate approximate derivatives of the function f. The derivatives of f with respect to xᵢ may be represented as df/dxᵢ. The derivative df/dxᵢ may be calculated by first finding a suitable delta, h, which is related to the size of the sketch. Then df/dxᵢ=[f([x₀, . . . xᵢ+h, . . . xₙ])−f([x₀, . . . xᵢ−h, . . . xₙ])]/2h.

Given a state vector x and the derivatives at x, df/dx, then client calculates an approximation of the solve function f at any other vector y by calculating y′=x+(y−x) df/dx. This may be used by the client to estimate any geometry solves while actively modifying the sketch by the user, thereby avoiding any delays in waiting on the server.

On the client side:

```
  dfdx := undefined
  x := sketch state vector
  approx := x
  do
    do
      y := new state vector modified by user drag
      send y to server
      if dfdx is defined then set approx := x + (y−x)
* dfdx
      draw approx
    until server response received or user stops
dragging
    if server response received
      set x := new state vector from server
      set dfdx: = new derivatives from server
    until user stops dragging
```

On the server side:

```
  when drag is received from client
    calculate new sketch state vector
    calculate derivatives with respect to coordinates
being changed by the user
    send new sketch state and derivatives to the client
```

This derivative approximation process may also be improved with an additional step to use of degrees of freedom information, which may be calculated by 3DGCS when calculating the sketch state vector. Degrees of freedom information constrains the movement of a dragged entity in a manner easily enforced by the client. As an example of such constrained movement, if a point is constrained to lie on a fixed circle, then the client can enforce that constraint before sending the change to the server and before calculating the approximation. This reduces variance in many cases.

The system can monitor, either entirely by the client or by the server tracking timestamp data provided by the client, the time required (delay time) from the client request through receipt of a complete solution from the server. A large delay time may be caused by a complex sketch or by a poor internet connection. In large delay time situations, the system may enable use of predictive drag dynamically to improve the user experience. A system wide setting may be configured, or individual settings configurable at a user account level, to establish a minimum delay time which, if exceeded, triggers enabling use of predictive drag. If already enabled, dropping below the minimum delay time would trigger disabling use of predictive drag. This dynamic enablement/disablement improves the user experience, by allowing continued local graphical operation and updating through use of predictive drag when delay time is large, and reducing extraneous graphical operation and updating by disabling predictive drag when delay time is minimal.

Part Studio

Referring again to FIG. 6, a Part Studio tab 610 can be used to define parts and can display a feature list (parametric history) 640, 642. Regenerating the feature list produces parts. The feature list drives the shape of multiple parts. Each part can be instanced multiple times in assemblies and each instance can move independently in the assembly. There are two main design tool aspects to the part studio: sketch tools and feature tools. Because a Part Studio allows multiple parts to be defined with one feature list, the user can design in a very productive top-down manner.

Feature Tools are used to create parts through manipulation of various features. The feature list includes entries referencing the origin and planes 640, entries referencing created features 642, and entries referencing parts 644. Created features are geometric operations (for example, but not limited to, a sketch or an extrusion) and the specific data associated with that operation. Selecting any entry in the feature list accesses user interface options to hide or show the selection within the graphics area, to suppress or unsuppress a feature (which visualizes the model with or without the feature being included), or to highlight the equivalent visuals in the graphics area. The feature list is sequentially ordered from top to bottom, so moving positions of features in the feature list reorders the design parametrically, which can alter the resulting design.

Sketch Tools 650 add or modify features in order to alter the displayed design. A specific sketch mode may be entered to orient the graphics area view onto a specific plane or planar surface, and then add or modify geometric shapes, points, and various constraints. Whether or not in sketch mode, various other options are available.

Extrude 652 adds or removes material perpendicular to a selected region, surface, or planar face. A dialog allows configuration of required entities, dimensions, and directions, allowing creation or modification of parts, or intersecting an extrude body with parts. Dimensions may be absolute (a measured and specific distance) or relative, such as up to: a next geometry, a specific surface, or a specific part; or through all parts.

Revolve 654 adds or removes material revolved about a selected sketch planar face or edge. A dialog allows configuration of required entities, dimensions, and directions to add a surface from edges or curves or create, add to, remove from, or intersect one or more solids. End conditions may be set such as a full revolution (360 degrees around a selected axis), in one direction for a specified angle, symmetrically in two directions for a specified angle, or in two directions at specified angles for each direction.

Sweep 656 adds or removes material along a specified set of connected curves. A dialog allows configuration of required entities, dimensions, and directions to add a surface or create, add to, or remove material from parts.

Fillet 658 rounds sharp edges to create round outside edges and filleted inside edges. A dialog allows configuration of required entities and dimensions to apply a standard, circular-shaped, constant radius fillet or a more stylized conic fillet. Required aspects include a specific edge or face of a part (which may apply to all edges of the face) and a radius value. Alternative options include tangent propagation (to automatically extend the fillet to tangent edges) or conic to apply a rho value for a more stylized fillet (allowing parabolic, elliptical, and hyperbolic curves).

Chamfer 660 applies a bevel feature to edges of a part. A dialog allows configuration of required entities (such as edges or faces) and dimensions (such as width for the chamfer). An optional tangent propagation may extend the selection along surrounding edges.

Draft 662 applies a taper to one or more selected faces in order to, for example, facilitate pulling a part from a mold. A dialog allows configuration of required entities (face of a part to act as a neutral plane), dimensions (degree of draft), and direction. An optional tangent propagation allows applying the draft to all tangent faces.

Shell 664 creates a thin-shelled part from a solid part by removing one or more faces and thickening the rest. A dialog allows configuration of required entities (one of more faces of a part to remove), and dimensions (thickness for remaining walls after removing the selected faces and hollowing out the rest of the part). An additional option allows selecting whether to create the shell wall by using the part face as the inside of the shell or the outside of the shell.

Pattern 666 allows replication of selected parts or faces. Linear patterns replicate in a row or grid, and circular patterns replicate around an axis. A dialog allows configuration of required entities (one or more parts or faces to replicate, and edge or face along or around which to replicate), dimensions (distance or degrees between repetitions and numbers of repetitions), and direction.

Mirror 668 allows mirroring one or more selected parts about a plane or planar face. A dialog allows selection of the parts to mirror and the plane or planar face. The created mirror parts are new parts independent of the original parts being mirrored.

Boolean 670 allows merging, differencing, or intersecting parts. A dialog allows configuration of required entities (parts) and operation. Union merges parts together, subtract spatially differences parts, and intersect removes material except where selected parts intersect. With the subtract option, an additional choice (keep) enables keeping the subtracted parts, which is useful when creating fitted parts.

Split 672 enables splitting an existing part into new parts. A dialog allows selection of the part to split and a plane or surface along which to split the part.

Transform 674 allows moving a part. A dialog allows selecting the part, type of move related entities or dimensions, and optionally retaining a separate copy of the part at the original location. Type of move may be by entity (moving based on another edge), by distance, by specific axis values (in x, y, z coordinates), or rotation about a selected axis.

Copy allows duplicating a part, with the duplicate being a new part independent of the original.

Delete 676 allows deletion of one or more parts. Once a part is deleted, it is removed from the parts list.

If parts are imported without any parametric history, some additional options to directly modify geometries can be useful. Modify fillet 678 allows altering or removing existing fillets. Delete face 680, move face 682, and replace face 684 allow modifying faces of a geometric part.

Plane 686 creates a construction plane, useful for orienting parts or creating new sketches. It can be based on any part, face, orientation, point, or line combination sufficient to define a plane.

Helix 688 uses a conical or cylindrical face to create a helix. A dialog allows configuration of entities (base conical or cylindrical face), dimensions (revolutions or helical pitch), and direction.

Rollback Bar

Referring again to FIG. 12, the model displayed in the graphics area is visualized up to the position of a Rollback bar 1230 in the Feature list. Dragging the Rollback bar to any position in the list visualizes the model at that point and allows inserting new features at that point in the parametric history. Because the feature list is a sequential ordering of features which, when applied in order, creates the current model, dragging the rollback bar to a set position allows regeneration of the model up to the point of the rollback bar. Features below the rollback bar remain listed but not applied as part of the currently displayed model.

Feature List Editing

The Feature list supports parametric history editing operations such as reordering features, deleting features, renaming features, and suppressing or unsuppressing features. It also allows easy access to manipulating the display by hiding and showing parts, sketches, and construction geometry and by changing graphical attributes such as color and opacity.

Mate Connectors

Mate connectors are local coordinate system entities located on or between parts and used within a mate to locate and orient part instances with respect to each other. Two part instances are positioned in an assembly by a mate. The positioning is done by aligning a mate connector defined on one instance with a mate connector defined on the other instance. The locations of these connectors may be points created when sketching or automatically generated inference points. The orientation of these connectors may be automatically inferenced, for example aligned with the coordinate system of a planar face or axis of a cylinder, or manually positioned. While manipulating a part viewed in the user interface, different inference points display based on the view and area of interest (such as mouse location). User interface controls (such as pressing a shift key) may prevent or change which inference points are displayed. Each face and edge of a part has default inference points at the centroid, midpoints, and corners (vertices). For cylindrical faces, inference points are on the axis of the cylinder and partial cylindrical face.

A dialog allows proper configuration when creating mate connectors. Mate connectors may be created on a part, or midway between two entities. A point is input (selected) to the dialog as part of the mate connector configuration. Further configuration options include alignment (allowing orientation change along a primary and/or secondary axis), movement (move the created connector a specified distance), and rotate (rotate the connector a specified number of degrees). Once created, mate connectors are listed in the Feature list, through which they may be selected for further modification or deletion.

A mate connector can be created in both the Assembly and the Part Studio. Creating a mate connector 690 in the Part Studio allows referencing sketch entities, which are available in the Part Studio but not aspects of parts available to assemblies. This allows more possible positions to define a mate connector within a Part Studio than in an Assembly. Additionally, a mate connector defined in a Part Studio is available for reuse on every instance of that part in every assembly in which it is instanced. When creating a mate connector in the Part Studio, there is an option in the mate connector dialog for identifying an Owner Part. This can be particularly beneficial when multiple parts exist within the same Part Studio.

Once created, users can hide or show mate connectors in both Part Studios and Assemblies. This can be done through context menus available in the Feature list and set individually or across all mate connectors.

Assembly

The assembly tab is used to define the structure and behavior of an Assembly. Each Assembly has its own Feature list that contains instances (of parts and sub-assemblies), mates, and mate connectors. An instance within an assembly is a reference to either a part defined in a Part Studio, or to a sub-assembly defined in another Assembly tab. Mates are used to position instances and to define how they move. Unlike traditional CAD systems, which typically use low-level assembly constraints to mate assembly entities (and, as a result, positioning two instances usually requires two or three of such constraints), mates are high-level entities. The movement (degrees of freedom) between two instances can be embedded in a mate. For example, a mate can define a pin slot relationship (or any other type of relationship between two instances).

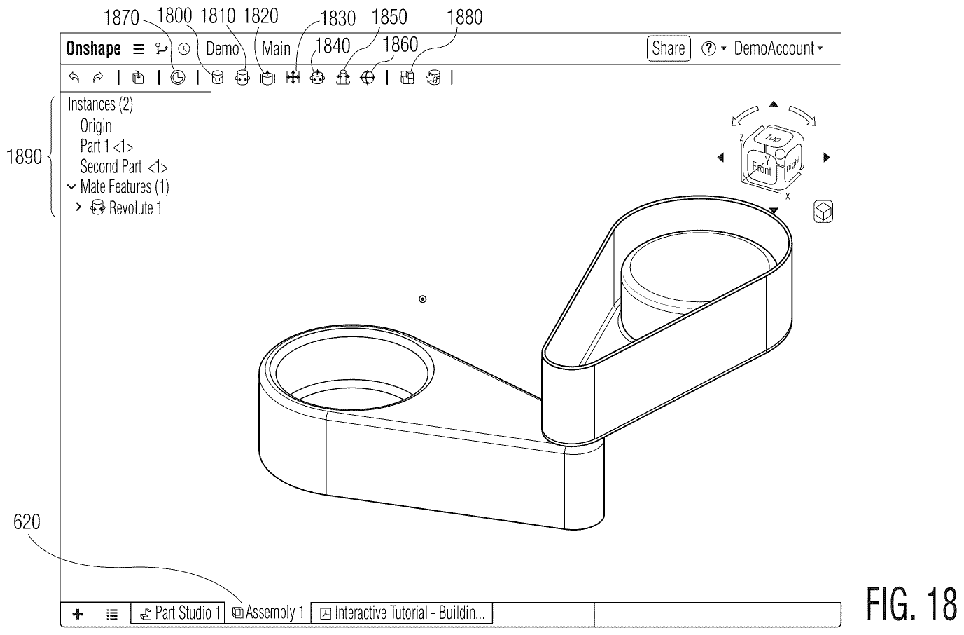

Referring to FIG. 18, the Assembly tab 620 is used to define and/or modify a hierarchical structure of part and sub-assembly instances which combine into an Assembly. It is also where users define how those instances can move. More than one Assembly tab can exist in a Project, and one assembly can instance one or more other assemblies (as sub-assemblies) and/or instance one or more parts. The basic steps to creating assemblies involve inserting instances of parts and sub-assemblies, creating mate connectors (where the instances connect), and creating mates (how the instances connect).

An insert dialog allows selecting parts and sub-assemblies for inclusion in an assembly. This allows selection of a specific part from a part studio, all parts in a part studio, or an assembly from a different assembly tab. Selection may be through any standard user interface selection technology, such as a search field for named search, or selection from an automatically populated list. An instance of the selection is then inserted into the active assembly tab. User interface interaction with the graphics area may position the inserted instance.

Once an instance is inserted into an Assembly, a user can move the instance through user interface controls. For example, click (or select) and movement may drag the instance (free drag). Another user interface control which may allow moving and repositioning instances around the graphics area, and for movement between instances, is a triad manipulator, which may be activated after selecting an instance to move. With the triad manipulator, a user may reposition the manipulator itself, move the instance along an axis or within the plane, or rotate the instance around the X, Y, or Z axis. When repositioning the manipulator, users can snap it to other entities in the Assembly to redefine the entity's position and orientation.

An instance which is not mated and not fixed will move exactly as a user specifies. An instance which is mated will move as directed within its degrees of freedom. Mates define movement between instances of parts and/or sub-assemblies. Each mate requires two instances, aligned through a mate connector on each, and definition of degrees of freedom (movement) allowed. Any two instances which move in constraint with each other have a single mate to define such movement, and only a single mate is required to define movement between those two instances.

When creating a mate, two instances are aligned based on a mate connector of each. This may result in incorrect orientation of one (or both) instances. A dialog for the mate may allow configuration of orientation, such as flipping a primary axis orientation or adjusting a secondary axis orientation in ninety degree increments. The mate may also be configured for a specific type of mating, which defines movement behavior (degrees of freedom within a standard X, Y, Z three-dimensional system). Fastened mates 1800 remove all degrees of freedom. Revolute mates 1810 allow rotational movement about a single axis. Slider mates 1820 allow translational movement about a single axis. Planar mates 1830 allow translational movement along two axis, and rotational movement along the third axis. Cylindrical mates 1840 allow translational and rotational movement along one axis. Pin slot mates 1850 allow rotational movement about one axis and translational movement along another axis. Ball mates 1860 allow rotational movement about all three axis. Positioning of instances is the same for all mate types (dependent on alignment of mate connectors), and the type of mating may be altered after creation to change the allowed movement between instances.

Mate connectors may be created as an aspect of part creation within a part studio or created within the assembly as a connector on an instance. Creating mate connectors 1870 within the assembly tab functions the same as creating the mate connector within a part studio, but is more restrictive when created within the assembly tab (cannot access underlying sketch entities for additional mate connector points, and will only be created for the instance within the assembly rather than available for every instance of a part).

In addition to mates with mate connectors, grouping 1880 is possible to fix relative positioning between instances. A dialog allows selection of multiple instances to fix as a group. Once fixed, movement of any instance within the group moves the entire group, keeping the relative positioning fixed. To move an individual instance within a group, a suppress option suppresses the entire group (allowing all instances to move independently), or a specific instance may be removed from the group (making that one instance independent but retaining fixed relative positioning between the other group members). When inserting instances of all parts from a part studio, they may be inserted as a group to automatically retain relative positioning as designed within the part studio. Adding a subassembly instance to a group makes the whole subassembly effectively rigid.

The assembly tab also contains an assembly feature list 1890, listing the instances, mates, groups, and mate connectors of the assembly. A user may select any individual list item in the feature list for modification or editing configuration. If the same part or sub-assembly is inserted multiple times into an assembly, the multiple instances are numbered within the assembly tab for user identification and individual control. Additional assembly feature list controls include hiding or showing any list entry, suppressing or unsuppressing any mate or instance, or “fixing” or “unfixing” an instance to prevent or allow movement of that instance within the assembly graphics area. When features are hidden, they are simply removed from the visual display but still part of the assembly. This can be highly useful in crowded or complicated models. When mates or instances are suppressed, the assembly is regenerated and displayed without the suppressed mates or instances. This can be highly useful to compare with a specific removal before permanently deleting it from the model.

Measuring Tools

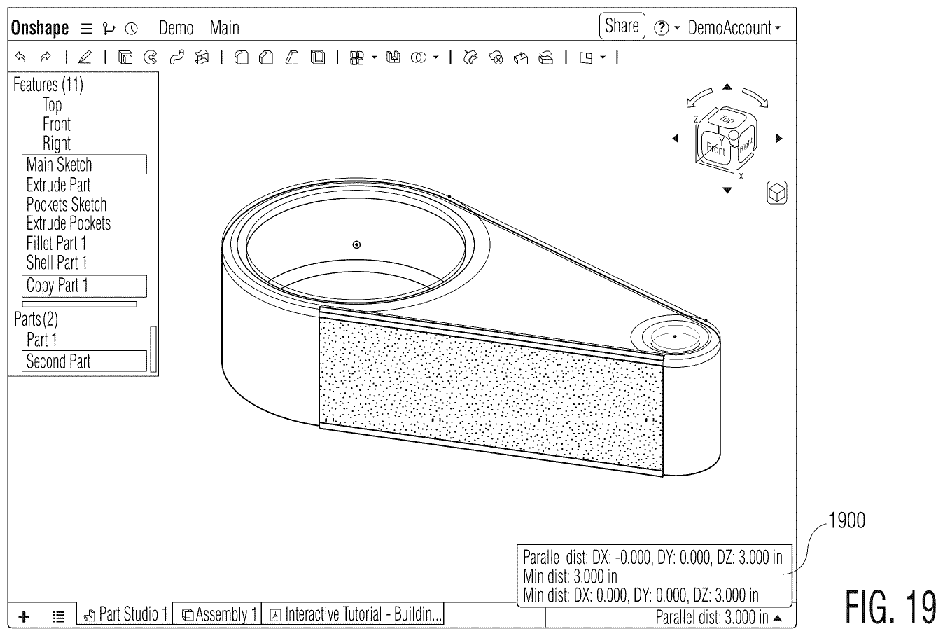

Referring to FIG. 19, within both part studios and assemblies, tools exist to measure dimensions or mass properties. After activating a measure tool, information about selected entities dimensions 1900 is displayed by the user interface. By selecting displayed measurement information, the measurement may also be visualized within the graphics area, such as showing minimum distances between entities as bold dotted lines, changes in various dimensions shown in red, green, or blue, and angles shown as thin dotted lines.

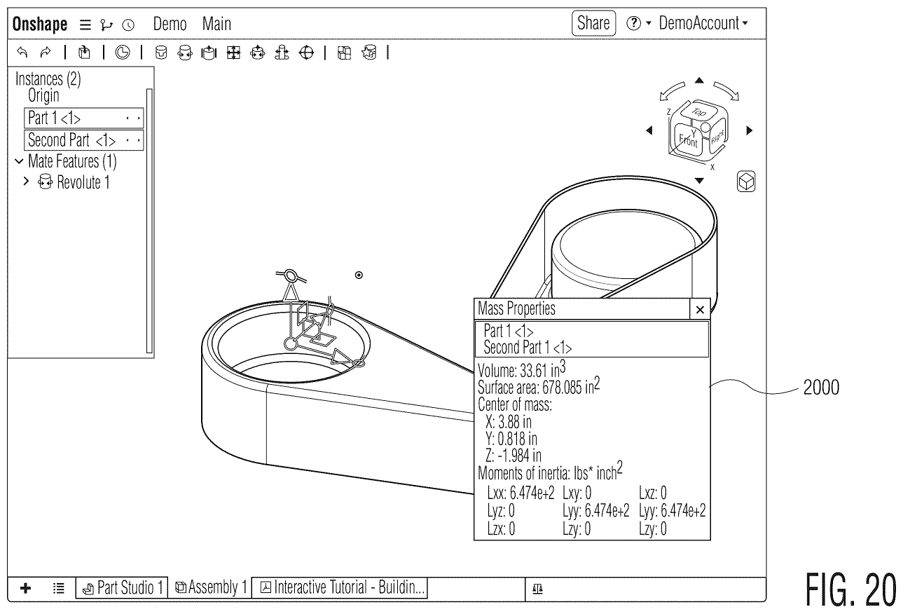

Referring to FIG. 20, after activating a mass properties tool, selected entities are cumulatively added. A dialog allows deleting (or adding) selected entities from the mass properties calculation, and selection of which mass property to calculate. Options to calculate include volume, surface area, center of mass, or moment of inertia (with respect to a common centroid of the selected entities, and assuming density of 1 in units used for the project or using density and other properties of material specifications associated with each of the entities), of the selected entities. For any intersecting parts, properties are calculated for each individual part and then added together. Calculations of properties are done by the 3DGCS and returned to the client for display in a mass properties dialog 2000.

History

While a user works within a project workspace, the DPS automatically records the state of each tab (Part Studio, Assemblies, etc.) at each persisted change made to any tab for the workspace. This persistent transaction history is listed in a History of the project. At any time, the user can restore all tabs in the currently active workspace to any particular prior point in its History. Every persisted change to a tab in a workspace is recorded in the project's History.

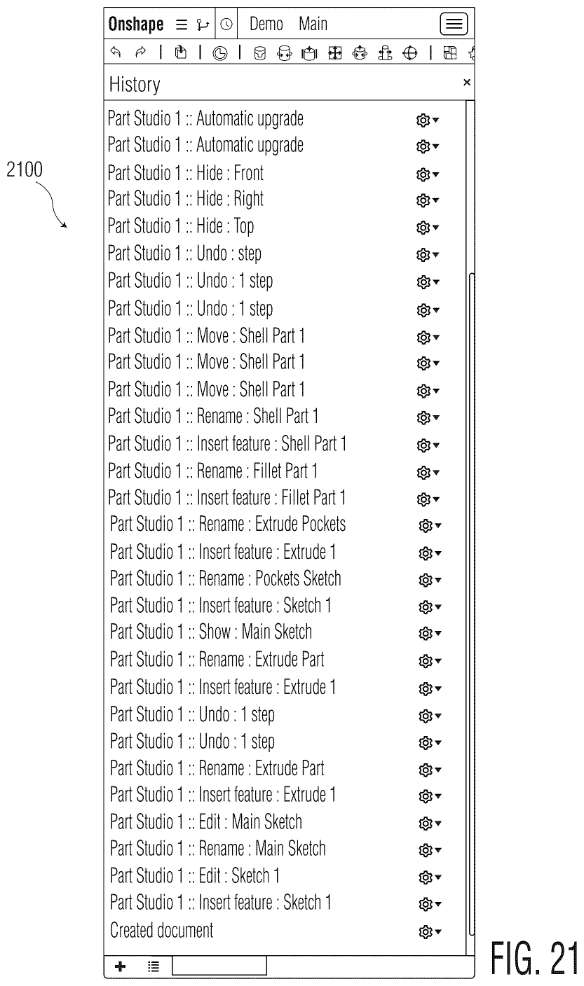

Referring to FIG. 21, records are listed for all tabs in the currently active workspace. The system captures the state of every tab in a workspace every time an edit is completed (by all users working in that workspace). This means that for every project there is a historical record of all states in which it has existed. As a result, users never have to worry about constantly saving their work. Users can always make changes with confidence that if the changes don't work out, they can find and restore any earlier state. In addition, users can use versions, branching, and merging to explore multiple design variations in parallel, either on their own or with other users. Restoring a project to a previous modification state can be used to reverse a design merge made through the Version Manager. The creation of workspaces and the merging of workspaces is also recorded in the persistent transaction history.

The description of a record in the History list 2100 may be in a format such as “Tab-name::Action:Feature-name.” Each entry in the History list includes displayable information (either by default or via user interface actions such as on-hover) to see who made the modification and when. Selecting an entry in the History list visualizes the project at that History point (including the feature listed). After visualizing at a particular History point, a Restore option is available to restore the workspace to that particular point. Such Restore action also becomes a record in the project's persistent transaction history.

A project may have many workspaces; one for each branch. At any point in time, a user can save a state of a workspace as immutable, thereby creating a version. A version is a snapshot of a project at a particular point in time. The geometric data (and the accompanying data like part names, etc.) of that version is unchangeable. This is a very valuable and unique feature. There are many references between parts and assemblies in CAD. In the prior art, these references cross stored named files and are “live”. This meant it was very easy to inadvertently change one file and unknowingly modify others. In many cases it is very difficult to know if such a follow-on change occurred and there is often no reasonable way to change one part without changing the referencing part. Such changes often impacted additional files recursively as well; a second part forcing a third part to change, and so on. This is a very serious and costly flaw in the prior art. In the disclosed system, references between projects are always to versions, and versions are immutable. Changes are made to a new workspace above the immutable version. When the workspace is versioned, the user receives a notification, and by taking a specific action, can control whether to update the referencing project or not.

Users can, however, change the metadata of a version. Users can create many versions of a project. Managing the workflow around versions and workspaces is performed through the Version Manager.

Version Manager

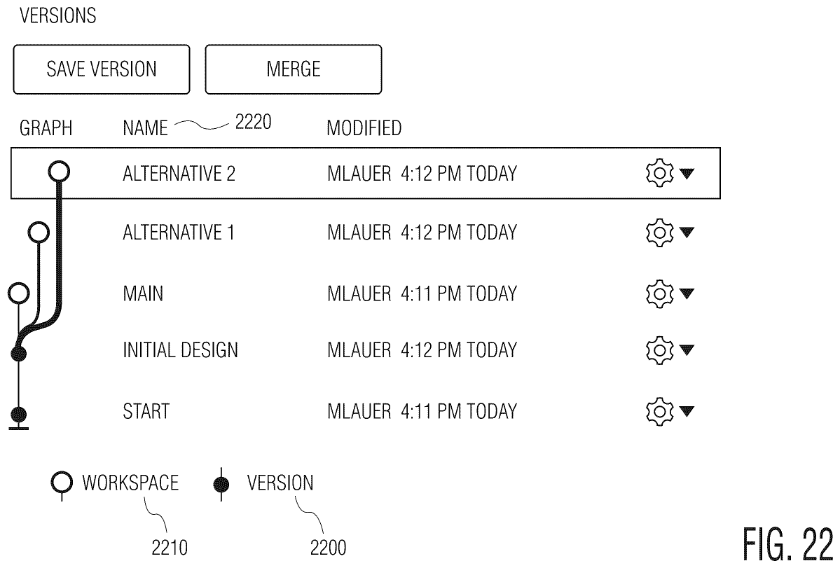

Referring to FIG. 22, the system provides a graphical representation of versions 2200 and workspaces 2210 in the Version Manager. As one or more users work in a project, each user can at any time mark a new version of the workspace. Users can also create a new workspace (branch) from a version. Note that marking a version and creating a new workspace are separate actions, as versions are read-only.

When viewing various versions, the name 2220 of the version appears beside the project title, and below that is a link to return to the workspace. Each version of a project is represented by a solid dot on the graph, and each workspace is indicated by an open circle. Users can create a new workspace from any version by selecting Branch from a user interface menu. Opposite to feature lists, the version graph grows from the bottom up with the first version of the project at the bottom of the graph.

Version actions include Open (open and switch to the graphics area for the selected version in view only mode), Open in new browser tab (open the selected version in a new browser tab in view only mode), Branch to create workspace (create a new branch and workspace from the selected version), and Properties (create or edit metadata about the selected version). Workspace actions include Open (switch to and open the graphics area for the selected workspace), Open in new browser tab (open the selected workspace in a new browser tab), History (view the persistent transaction history records for the selected workspace), Properties (create or edit metadata for the selected workspace), and Delete (delete the selected workspace; note that users cannot delete the last remaining workspace—to do so requires deleting the entire project).

Real world use cases illustrate examples which leverage the Version Manager functionality. When developing multiple variants independently, or when seeking regulatory approval in any number of different markets, users may use the Version Manager for a number of largely independent development efforts all contained in a single project. Each branch may hold changes specific to that market, and the various parts and projects would reach release and regulatory approval states at different times. Another example use is when branching an initial design to evaluate a number of competing concepts with only one being chosen to develop to a release state. Another example use is when a large group of designers want to work independently on a number of ideas or changes that may or may not make it into the final design.

Sharing

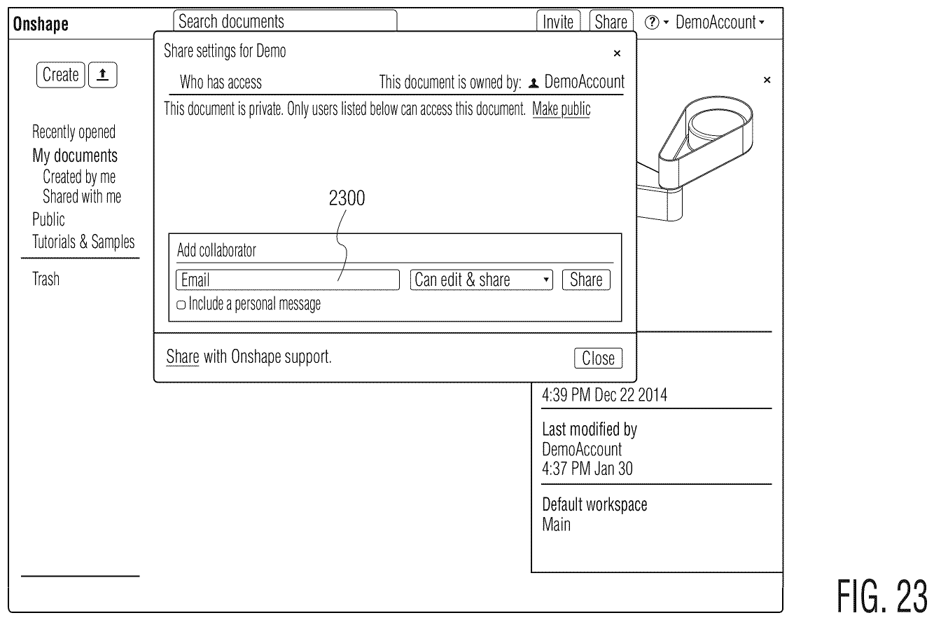

Referring to FIG. 23, the system enables simultaneous editing between multiple users. Users can share a project with whomever they want by entering the email address 2300 of someone to share it. Upon sharing, the DPS, AMBS, and AMCS generate an email notification about the shared project. If the share recipient is a registered user, the shared project is made available within that account. If the share recipient is not yet registered, the emailed notification includes information about creating an account in order to access the shared project. Different share permissions are available, including view (read-only), edit (read and edit), and edit & share (read, edit, and extend permissions to other users), and may be set when sharing or changed at any later point.

The user can choose to disallow any operations in the system that would allow the user to make copies of or download the data in the document. This could be available at any permission level. In other words, the sharee could be allowed to work within the document in a read-only manner or to edit the document. The sharee's access can also be removed whenever the user desires. These capabilities give the user greater control over who can access his data, how long they can access it, and how they can access it using the system. In prior CAD systems, data could only be shared by sending the sharee a copy of the file. Once the file was copied, the initial user no longer had any visibility or control over who accessed that file and who they distributed it too.

Projects allow both simultaneous editing (many users working together in one workspace of a project simultaneously) and branched editing (many users working independently but in parallel workspaces of a project with the ability to compare and merge later).

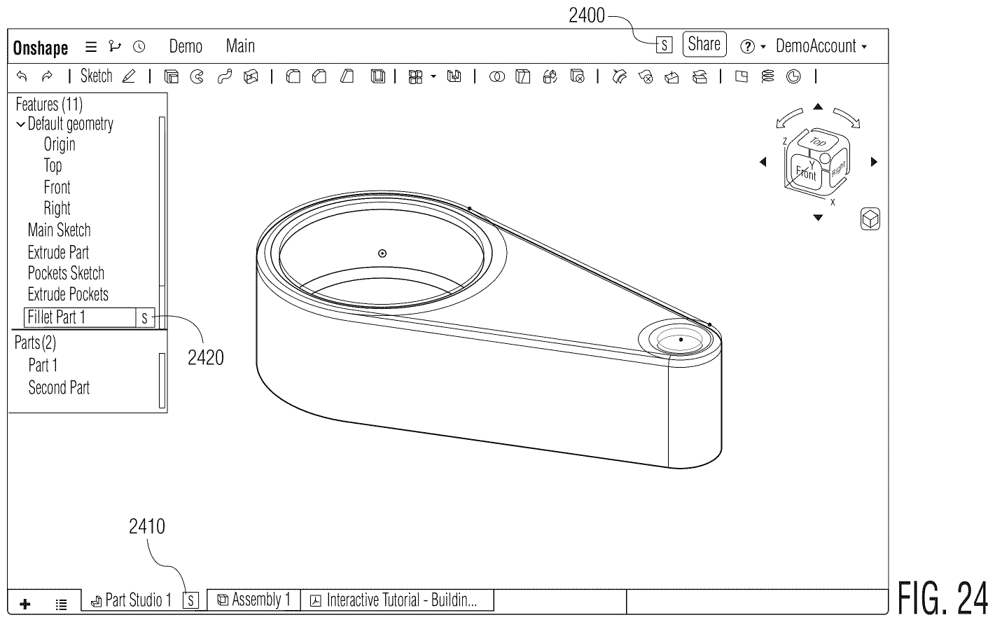

Referring to FIG. 24, users can work in the same project workspace at the same time, referred to as Simultaneous Editing. The creator of the project must Share it with the other users before they can collaborate. Within shared projects, social cues indicate what is being edited. Social cues may be graphical indicators, such as a colored box with letter indication an initial of a specific user's name, placed to identify who is viewing a project, which tab they are currently viewing, and any feature list items actively being viewed or edited. At the top is indication 2400 of who is actively viewing or editing the project. At the bottom, social cues 2410 in a tab indicate who is actively viewing or editing a file. At the side, social cues 2420 within the feature list or assembly feature list indicate users actively editing specific feature or assembly entities.

Branching

A user always works in an active workspace. A project may have many workspaces, which under most circumstances do not interact with each other. Any changes a user makes within an active workspace are immediately reflected in that workspace and not in any others; any collaborators in the same workspace are immediately updated.

A user may bookmark a particular state of a project workspace for future reference by saving a version, a permanent and immutable state of the project. A user may branch by creating a new workspace at a given version. The initial state of the project in the new workspace is identical to that of the version. Workspaces and versions form a directed acyclic graph with a “parent” relationship; the first “parent” of a workspace being the version it was branched from, and the parent of a version being the parent version of the workspace it was saved from. As described so far, the graph is actually a tree.

Merging

Project branches (separate workspaces within the same project) may be merged together. A basic merging scenario involves one branch which contains all newer changes from another branch, and the user merging from that branch into the one to update. A more complex merging scenario involves a main workspace, or master design, and multiple branched workspaces for developing changes, with merging intended to incorporate some changes across multiple branches into the main workspace.

To handle all merging scenarios within a CAD system, the parametric history of each branch is compared as a linear list of features, with corresponding graphical representations. This is presented to a user to compare the two lists side by side textually in a similar manner to software comparison tools. The user may select or highlight any particular feature step in the parametric history, which optionally may display updated side-by-side or merged 3D graphical representations of each workspace at that feature step. This means that the user can both textually and visually understand the differences between the two models at that feature step. In addition to the text and graphical displays, dialogs for the selected feature for each branch may display with values from each workspace, and differences may be identified within the user interface such as through highlighting.

From the selected features, the user may incrementally push (merge) a change from one workspace into the other. The servers then regenerate the merged workspace incorporating the change, and the merge itself is tracked as a new change within the persistent transaction history of the workspace.

In this regard the system is doing much more than the similar compare and diff tools currently do in traditional software development. The CAD user sees three representations of the data (feature list, feature dialog, and graphical 3D model) of each different workspace of the project. The CAD user sees the actual regeneration results side by side at that step. In software, the analogy would be a tool that not only compared the text side-by-side, but also compiled and ran the program—and showed the different running programs in results.

With merging different branches, it is assumed that the definition of the shapes of parts occurs in a part modeling environment with a parametric history (Part Studio), and the definition of the assembly occurs in a separate assembly modeling environment (Assembly). The merging discussed above is focused on the part modeling environment.

In the assembly modeling environment, as described above with respect to parts, any assembly can be deconstructed into a linear set of operations that construct the assembly. For example, an assembly can be deconstructed into a set of instance insertion steps, followed by a set of positioning steps (that position the instances in 3d space), followed by a set of constraint definition steps. There are other deconstructions that would work just as well—this is just one example.

Through deconstruction the assembly can be represented as a set of steps. These steps will generally be different and in a different order than the steps (feature list) the user actually used to create the assembly (unlike in the parametric part history). Nevertheless, they are easily understood by the user since they correspond to interactive tools that the CAD user uses to create assemblies.

Using these steps, and the user interface (such as dialogs) for the interactive tools, the assembly steps can be presented to the user in the same manner as the part feature steps were. The visual compare and incremental merge tools can then be used to compare and edit the assemblies.

Text-Feature-Editing

The feature selection with graphical correspondence discussed within merging exists during normal editing within a project. Making a selection within the graphics area may highlight or activate corresponding entries in the feature, and selecting within the feature list may highlight corresponding entities within the graphics area.

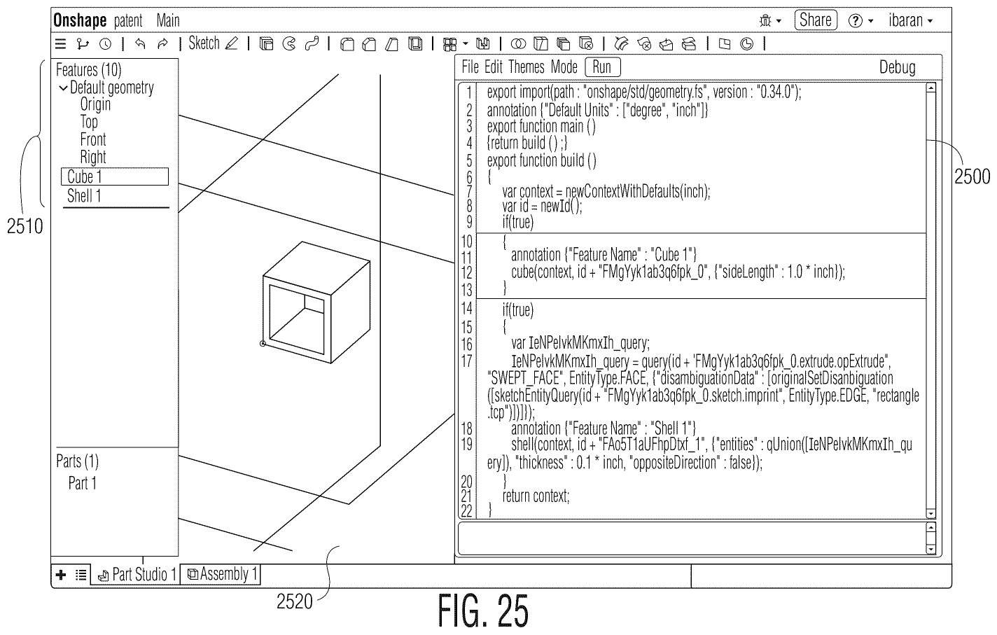

Referring to FIG. 25, this may be extended even further, and include a third representation as a code or script. The underlying implementation may maintain an abstract syntax tree (AST) 2500 of an object-oriented representation of a program corresponding to the CAD model, including the parametric feature list. Each entry in the feature list, with feature parameters and model definition components, corresponds to one or more subtrees of the AST. This correspondence allows cross-highlighting between the feature list 2510, a textual representation of the program 2500, and graphical display 2520. An optional overlay may display the textual representation, and enable three different, but corresponding, editing options. Edits to the feature tree, graphical area, or textual representation may be correspondingly updated across all three editing options. Similarly, when a user moves a user interface control (e.g., the mouse pointer) over a feature or another portion of the GUI representation, the corresponding portion of the program text is highlighted.

Reference Manager

When working with a CAD design, many geometric elements may be created based on other geometries. The geometry and relationship data are tracked as references between objects. When working within a single parametric history, making any change can be visualized from the point of change all the way to the final design (with all later features also applied). When working with multiple parametric histories, the problem of any single change becomes more complex. With multiple part files and assemblies, making a change within one parametric history can trigger changes (and errors) within others.

When the related objects are generated by distinctly separate parametric histories in the context of an assembly, they are referred to as in-context references. When the context changes, by either changing the surrounding objects or removing an object from the context altogether for reuse elsewhere, references may become invalid and subsequently difficult to manage. A Reference Manager maintains a local context to keep these references in a valid, solvable state. Additionally, the Reference Manager provides a notification mechanism to inform users when in-context references are out of sync and provides options for maintaining desired design intent.

The Reference Manager can be viewed as a tool to help a user through unresolved references by notification when unresolved conditions exist, flagging affected items, and offering resolution options. The Reference Manager is preferably a module operated by the CEWS. As a separate module, the Reference Manager may be operated as a separate module and also integrated into other CAD systems (either as a separate module or directly as part of a main CAD software program). Thus, the Reference Manager may operate for multiple parametric histories within a project of the system for references within a project which instance parametric histories (parts or sub-assemblies) and/or other parameter values, text, or other non-geometric data outside of the project's compound document, or for other CAD systems which use different storage techniques for parts and assemblies used instanced in a CAD design. Changing the geometry of any individual part can impact the assembly containing the part being changed, as well as any other assembly containing the part. The change can have an expanding greater impact if geometries of other parts are also changed to accommodate the change to the initial part. Changes may also impact other part features if they depend on the geometry of the part being changed. To ensure stable design while making part changes, the Reference Manager maintains copies of parts pre-change, inspects and tracks references of an assembly, redefines references when possible based on user changes, identifies and provides notification for out-of-sync conditions, and provides user options on how to handle out-of-sync conditions.

In-context references may be created in multiple different ways. In-context references may be created by sketches within the one parametric history referencing instances of parts created within a separate parametric history.

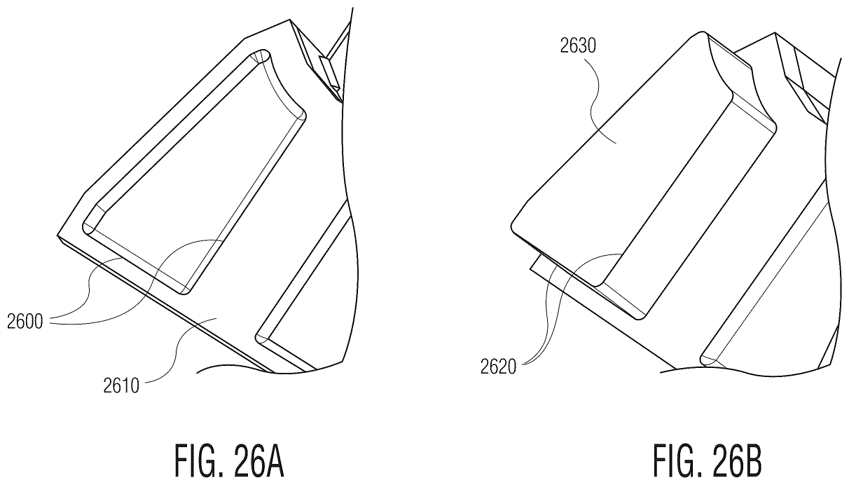

Referring to FIGS. 26A & 26B, one example of this is using one or more edges 2600 of one or more parts 2610 to define one or more the edges 2620 of another part 2630. As another example, a sketch may be on a plane generated from another parametric history.

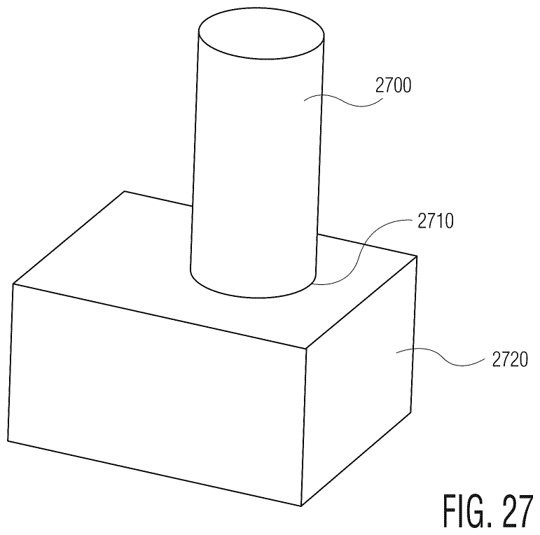

Referring to FIG. 27, in-context references may also be created by features, such as defining end conditions for one part which depend on other parts (as shown, the cylinder 2700 bottom 2710 is defined by the top of the rectangular block 2720), defining one part's interaction with another part (such as to added to, subtracted from, or intersected with), specifying a face to split a body with, or defining a reference axis for rotation or reference edge for a pattern. References may also be created from an equations and variant table, which may contain expressions determining geometry such as a length or a line, or other dimensional value. All of the above refer to creation methods where items from one parametric history use items generated by a separate parametric history.

When an in-context reference is created, the Reference Manager creates a back-up geometry. The back-up geometry is a copy of a portion of the referenced object as it was at the time of reference creation. By maintaining a copy of the original referenced geometry, the system can treat the resultant object as independent with no dependency on the parent if desired. Instead of requiring the parent (or target) object to always be present and viable, this maintains completely resolved and correct objects independent of changes made in other parametric histories. Changes made in other parametric histories can be applied but are not forced to be applied due to the backup geometry.

When geometry or parameters of a part are changed, the Reference Manager examines references to determine if any problems have been introduced. Problems include assemblies or sub-assemblies which cannot regenerate after the change due to unsolvable conditions or conditions that results in multiple different possible solutions.

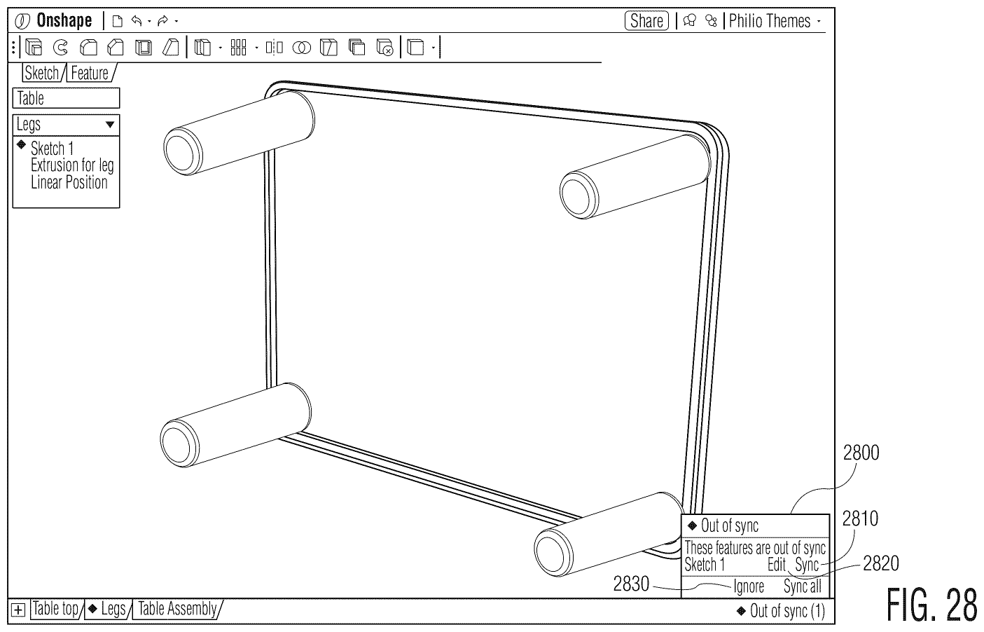

Referring to FIG. 28, if an out-of-sync condition exists due to a change in a separate parametric history altering a part used, notification 2800 is raised for the condition. Notification may be in the form of a flashed message or alert within the user interface, graphical indication on at tab having out-of-sync objects, textual identification of the number of out-of-sync objects, and graphical indication within the feature list of any features or parts which are out-of-sync. A user may select any of the notifications or corresponding graphics to address the out-of-sync conditions. From the selection, the user may sync 2810 or update with the changed (new) geometry. This selection causes the reference manager to replace the backup geometry with the changed geometry and solve (through the 3DGCS) the new result.

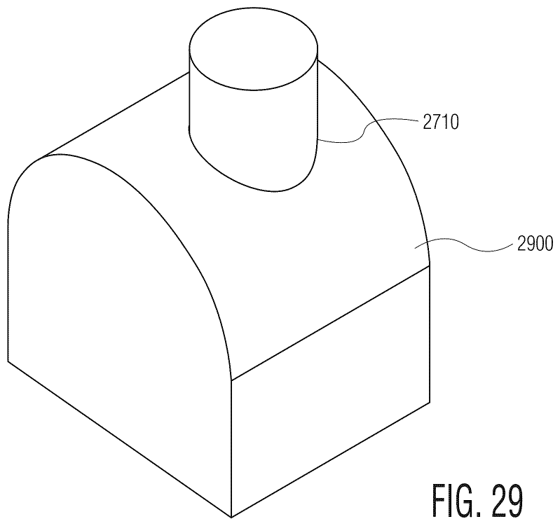

Referring to FIG. 29, the cylinder bottom 2710 of FIG. 27 now curves to still align with the changed lower block 2900. If the change results in an alterable error condition, such as an editable feature is no longer resolvable, that editable entity (e.g., feature dialog) with error information may be presented to the user. Alternatively to synchronizing and updating, if the reference is to an editable entity (e.g., a configurable feature), the user may choose to directly edit 2820 (referring to FIG. 28) that entity, after which the out-of-sync reference may be replaced by the result of the edit.

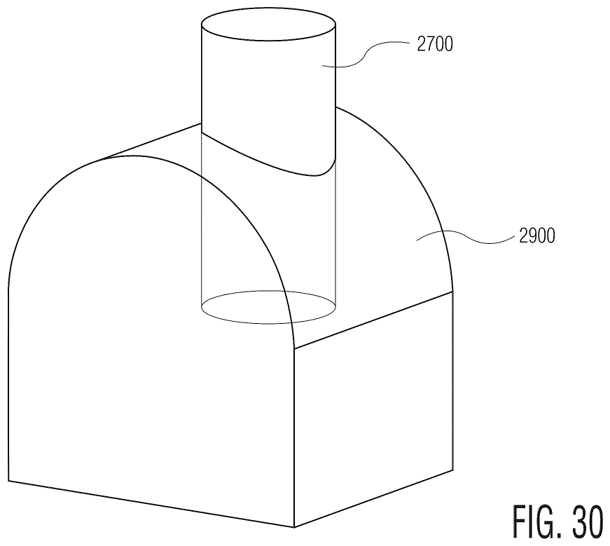

Referring also to FIG. 30, as another alternative, the user may choose to dismiss 2830 (referring to FIG. 28) the changed reference. By selecting to dismiss, the changed geometry is ignored and the backup geometry is retained and used, maintaining the design in a solved state. As shown, the cylinder 2700 retains its prior shape with reference to the original block geometry, and therefore penetrates through the changed block 2900. If multiple out-of-sync references exist, the user may also choose to synchronize all or dismiss all, or synchronize or dismiss a selected set, rather than addressing each individually. Dismissing will retain a valid model (with the backup geometries), but synchronizing may result in errors needing correction from the user. Unresolvable references when synchronizing all are maintained in the out-of-sync state, allowing the user to individually address each reference or, alternatively, attempt to synchronize all again in case nested reference updates allow previously unresolvable references to resolve.

The Reference Manager may similarly track assembly components connected through mate connectors. As an example, a component may be removed from an assembly in which it has been mated. A mate relationship is “attached” to the component, but unresolved because the corresponding geometry from its original mate component is no longer there. When the component is inserted into a new assembly context, the mate needs to be re-attached to a new corresponding geometry. Back-up geometry may be utilized to find a proper match or inform the user to help them with manual attachment.

Simulation of Parts and Assemblies

Simulation can be used to evaluate the stresses and displacements between externally-loaded instances in an Assembly, allowing a user to examine how an assembly reflects the loads, materials, and boundary conditions found in real-world use. Simulation can support structural linear static finite element analysis.

Product designers and engineers can use simulation to test models early in the design and prototyping process. A designer can interactively change materials, loads, constraints, or results, and compare multiple simulations, viewing these results immediately. This reduces the need for costly prototype iterations and optimizes models to better meet specific design criteria.

Load Objects & Configurability

The disclosed unified simulation and CAD modeling environment can be configured to support one or more types of analysis. The description that follows will focus on structural linear analysis, but other types of analysis, such as modal analysis, can be included and made available for simulations. When performing a structural linear analysis simulation, at least one load is required for each simulation that a user may wish to investigate. However, it is common that a user would wish to investigate multiple simulations or load cases for a single CAD model, and typically each load case requires a unique set of loads.

Each simulation, including the structural loads which characterize it, can be made part of an Assembly. These loads may be reconfigured across multiple simulations, and each simulation may be reapplied across multiple assembly configurations. Interactions between instances can be inferred from mates, eliminating needless re-authoring of the model. In one embodiment, simulation results will always reflect the current state of a model. Since each load is an artifact of the Assembly, not the simulation, that object can be configured (both in magnitude, vector, and suppression state) across multiple load cases. The distinction is subtle but greatly reduces the overhead and “accounting” associated with simulation analysis, and it is a novel advancement.

Automatic Representation of Mates as Implicit Simulation Interactions

As discussed above with reference to the System platform, Mates and Mate Connectors are connection points and connection types that allow designers to assemble parts in a physically intuitive manner. Simulation requires similar information in order to operate, but its definition of interactions has traditionally been separate from or redundant to the assembly model definition. The disclosed simulation environment leverages mates for every physical interaction and constraint imposed upon parts, greatly reducing the overhead of analysis.

The simulation environment leverages an “immersed” meshing scheme, which granularizes simulation bodies into voxels that overlap with one another when within sufficient proximity to one another. If a mate has been declared between two parts, the system then restricts the associated degrees of freedom respective to the mate in the areas in which those parts are within proximity. In this manner, the simulation interaction is implicitly derived from the part position and mateship.

This capability relieves users of considerable explicit authorship of the simulation model, whilst not interfering with the Assembly model's conventional (geometric) behavior. This ease does, at times, result in less precision of the simulation interaction regions. For that reason, the environment can support enhanced mates with a Simulation Connection capability, which allows the user to specify precisely which faces or regions the simulation interaction may affect. These Simulation Connections can be configurable features, meaning that the user need only identify the connection region as a variable to investigate, which can then be investigated with the toggle of a button, instead of completely re-authoring a separate simulation model.

In whole, the behavior of mates as implicit interactions may be thought of in terms of a Venn Diagram. Assembly mates can operate between parts in the conventional Assembly context regardless of proximity (no overlap in Venn Diagram). Assembly mates can operate as simulation interactions only where two parts are within physical proximity (coincidence or overlap in Venn Diagram). Finally, Simulation Interactions enrich mates with specific regions over which simulation interactions may operate, should the two parts also be within proximity of one another (third body in Venn Diagram).

Multiple Mate/Interaction Default Settings

In the disclosed system, simulation interactions can be primarily inferred by the physical proximity of parts, and the rules of that interaction can be most precisely described by an assembly mate. However, to further ease the user, the environment supports the following rules, or default settings, for simulation interaction behavior when mates may, or may not, be present in the Assembly:
Honor simulation interactions only if a mate has been explicitly defined;
Honor any mate definition and assume any other parts within proximity of one another are meant to be Fastened (fully fixed) along their interface; and
Assume all parts, regardless of mate definition, are to be Fastened (fully fixed) along their interface.

Optional additional rules can include:
Honor any mate definition and assume any other parts within proximity of one another are meant to be constrained by the rules associated by some mate type, not necessarily Fastened, as specified by the user;
Honor any mate definition and assume any other parts within proximity of one another are meant to be constrained by non-penetrative Contact; and
Assume all parts, regardless of mate definition, are to be constrained through non-penetrative Contact.

It should be stressed that these simple rules for implicit interaction recognition are considerable time saving and troubleshooting devices for the user. It is a non-trivial effort to realistically constrain an assembly of any significant size or complexity, and implicit definition is a considerably valuable technology.

Connection and Non-Connection Visualization

Since each interaction is inherently based on part proximity, a connection visualization tool (the output of which is referenced below as a Show connections checklist 3402) pre-computes the effective proximity range for each part and scans each part pair to see if, and where, any two are within either's range. If such a region is detected, those areas are noted in space and rendered to the user interface. These areas are then colored and labeled by their explicitly-Mated or default-defined interaction type, giving the user a comprehensive view of where and how simulation interactions will be enforced. Furthermore, if two parts are not interacting, but are within interaction proximity of one another, those regions are rendered with yet a different, specific color.

When coupled with default interaction rulesets, the ease of authoring a complete simulation model exceeds prior solutions. The rendering of proximate, but not-interacting parts is of novel benefit, because users tend to fail by under-constraining, not over-constraining, their simulation model.

Simulation User Interface

FIGS. 31A-C show a user interface for performing simulations of static loads in a CAD environment. Referring to FIG. 31A, a Simulation box 3102 is indicated at the top of an Assembly list on the left side of the screen, just above the Instances list. A drop down menu 3103 within the Simulation box 3102 allows a user to select from multiple simulations they may be working with and shows an editable label for the currently selected simulation. A Show Results checkbox 3104 can be checked by the user to begin showing the results of a simulation. A Status icon 3106 indicates the current status of the simulation. If the simulation is in an error state, as shown in FIG. 31A, a yellow warning icon is shown to the right of the Status label. Hovering over the icon provides a tooltip to indicate the error and offers a suggestion on how to fix the error. In FIG. 31A a warning indicator explains that a fixed instance is required before a simulation can be performed.

FIG. 31B shows that the part PIN<1> 3108 has been fixed, which was accomplished by selecting it with a right-click in the Assembly list to bring up a context menu and then selecting a “fix” menu option. The part PIN<1> 3108 then shows an icon next to its entry in the Assembly list indicating that it is fixed.

Simulation Load Tools

When performing a structural linear static analysis, a simulation cannot be performed until at least one load is assigned to an Assembly. Loads can be assigned on an instance-by-instance basis, with no limit to the number or type that may be assigned to any instance, with the exception of a fixed part/instance, which, in reference to the simulation, is immutable. A load cannot affect any change to or through a fixed part/instance.

FIG. 31B also illustrates a load dropdown menu 3110 showing a number of simulation load tools. In one embodiment, there are five load tools: Force, Moment, Bearing, Pressure, and Acceleration as follows.
The Force tool 3112 simulates the effect of an evenly distributed, linear force on an instance. By default, the force is distributed throughout the instance's volume. If, instead, a load region is enabled, and specific faces of the instance selected, the force is distributed evenly over the faces.
The Moment tool 3114 simulates the effect of an evenly distributed Moment (torque) on an instance. By default, this moment is distributed throughout the instance's volume. If instead a load region is enabled, and specific faces of the instance selected, the moment is evenly distributed over the faces.
The Bearing tool 3116 simulates the effect of a bearing load on the surfaces of an instance. This Bearing load produces the total equivalent load as a force, but it is only applied to an instance's faces, and its distribution is not uniform (unless all surfaces are coplanar). Instead of an even distribution, Bearing distributes its load proportionate to the degree to which it is aligned normal to, and facing toward, the loaded surfaces. If the bearing load has no positive projection onto the loaded surfaces, it contributes no load to the simulation.
The Pressure tool 3118 simulates the effect of an evenly distributed Pressure on the surfaces of an instance. Similar to a Bearing load, Pressure is only applied to an instance's faces. Pressure magnitude is only positive, but by toggling the load direction arrow, it either pushes into a surface (default) or pulls away from a surface (suction). There are two ways to apply a pressure load. First, in the Instance field, by selecting an Assembly instance, pressure is loaded on any instance the selected instance touches, not the selected instance. Second, in the load region field, by selecting all faces to which the pressure is to be applied, the pressure is applied to the selected faces of the instance.
The Acceleration tool 3120 simulates the effect of a static, uniform, linear acceleration acting on an instance. Acceleration is only applied to the whole instance; individual faces cannot be loaded. The result of an Acceleration load on an instance is precisely equivalent to that of a proportional force applied to the same instance, in the same direction, if the mass of the instance is taken into account.

FIG. 31B also shows a Force tools dialog box 3130, which is opened once a Force simulation load tool is selected. The dialog box 3130 can include the following fields.
Load 3130 (shown as “Force 1” in FIG. 31B)—This is an editable load label, which is used under the Loads dropdown in the Assembly Instance list and the Simulation panel.
Load dropdown 3132 (shown as “Force” in FIG. 31B)—This dropdown can be used to switch between tools for the current load, for example, from Force to Moment (as has been done in FIG. 31C, described below).
Instance 3134—The instance in the assembly on which the load is applied. Only one instance can be selected in this field. Multiple instances are not supported. In FIG. 31B, the instance selected is the PIN<2> 3109.
Faces to load (not shown in FIG. 31B, shown for Bearing and Pressure loads only)—With Bearing and Pressure loads, the loads must be applied directly to the instance faces. Any number of faces may be selected, but they must all belong to the Instance identified in the Instance field.
Load direction 3136—With this field highlighted, a user can select an existing mate connector or click on a location to create a new mate connector that drives the load direction (note that a new mate connector created here to drive the load direction cannot be referenced anywhere else in the Assembly). By default, loads are aligned with the mate connector's Z-Axis; the reverse arrow icon to reverse the direction of the load. A Pressure load does not require a mate connector to define its direction. A user can use the reverse arrow icon 3302 to switch between pushing into and pulling away from the surface. Load direction is configurable on a simulation-by-simulation basis. In FIG. 31B, the Load Direction is specified with respect to a mate connector of BLOCK<1>3137.
X/Y/Z Magnitude 3138—This field is a numerical value of the load being borne by the instance. Pressure requires only a single Magnitude entry. When applying a Load Direction in the Load dialog, the mate connector's X, Y, and Z axes are used as the coordinate system to drive the corresponding load direction's X, Y, and Z axes and related directional loads. Magnitudes are configurable on a simulation-by-simulation basis.
Load region 3140—By default, the load is borne by the instance. To localize the applied load to only part of the instance, the Load region box can be selected. Then, one or more faces of the instance bearing the load can be selected. Bearing and Pressure do not have a Load region checkbox but do require selection of Faces to load. Acceleration does not have a Load region option.

FIG. 31C shows the Force tools dialog 3130 of FIG. 31B after a user has selected the Load dropdown 3132 and then selected Moment (from a list of Force, Moment, Bearing, Pressure, and Acceleration) to change the Force load to a Moment load along with a selection of the value for the Moment load for purposes of a simulation.

Simulation Results

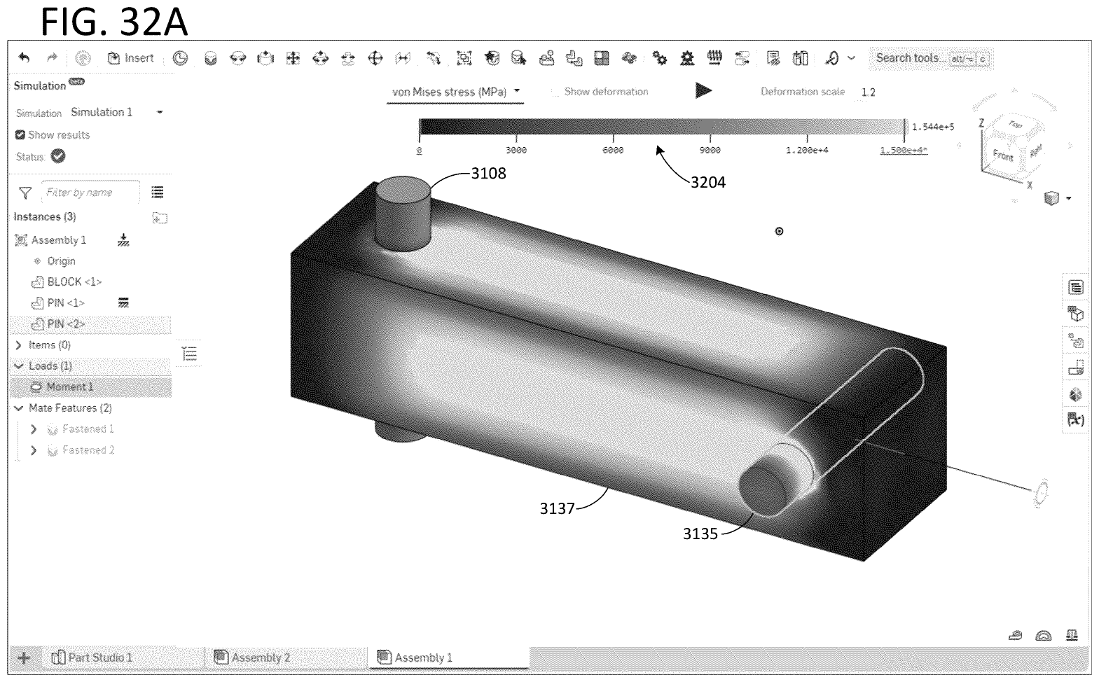

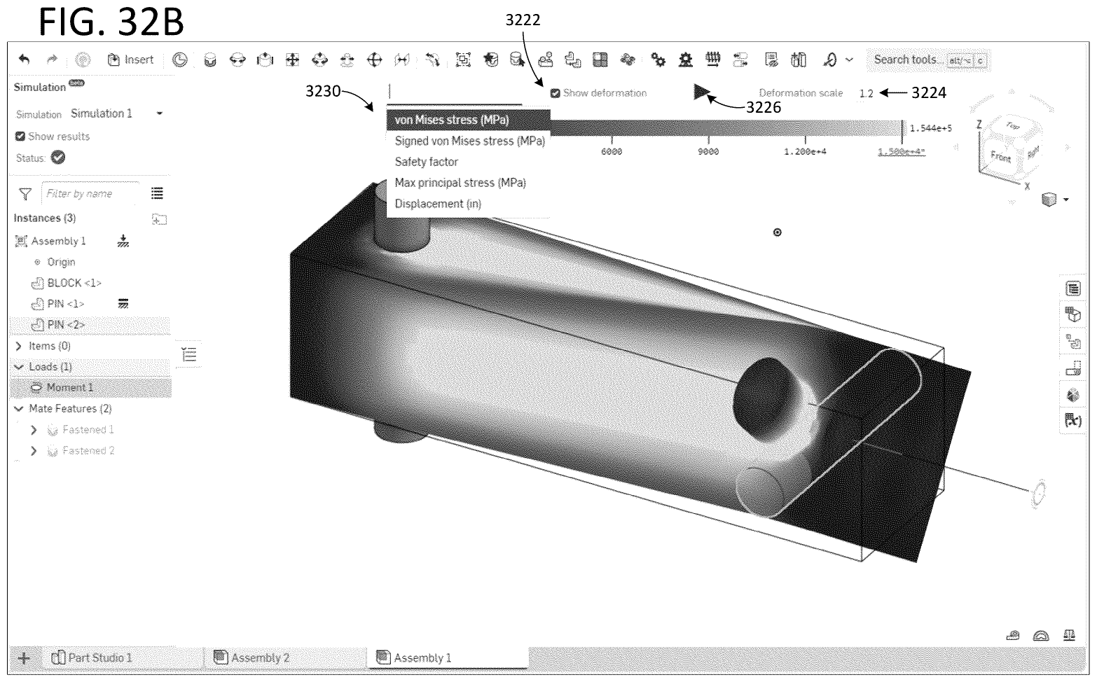

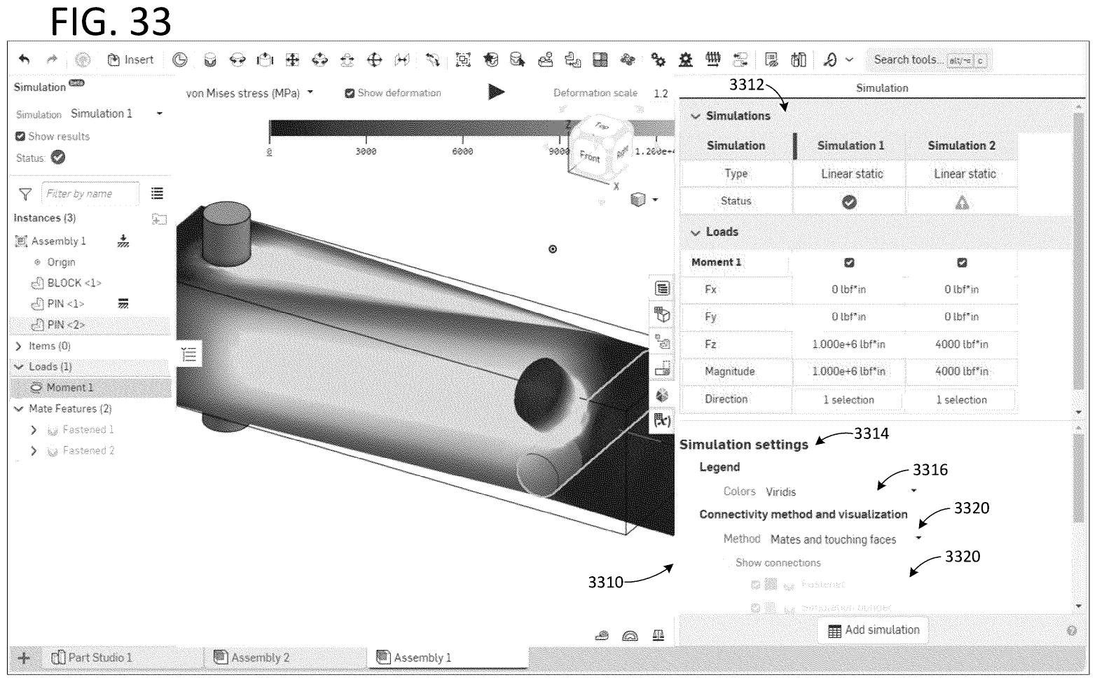

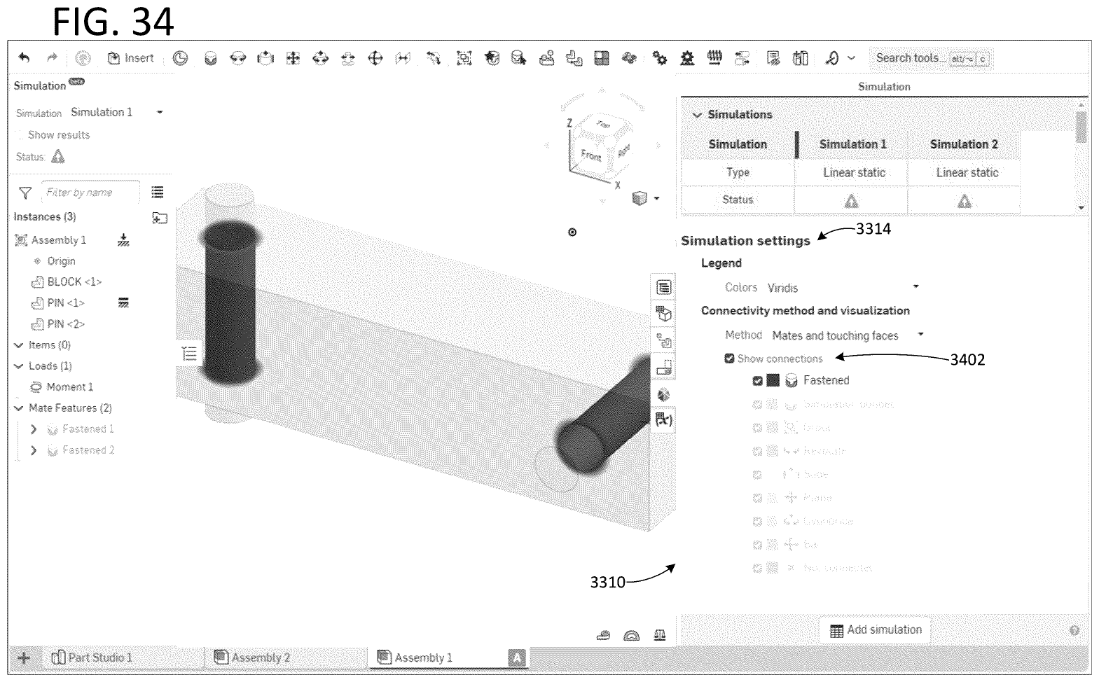

FIG. 32A illustrates a user interface showing the results of a simulation of an example assembly when the Show Results checkbox 3104 is checked. In the illustrated example, a moment load is placed on PIN<2> 3109 (highlighted) passing through a right side of a solid block of material while PIN<1> 3108 on the left side is held fixed. A color scale 3204 represents the load measurements from lowest to highest. A user can click the lower or upper scale link to numerically enter the minimum and maximum scale values. A user can click the Reset icon to the right of these numbers to reset the minimum or maximum to the default value.

FIG. 32B illustrates the same user interface after a user has selected the checkbox option 3222 to “Show deformation” in order to display the deformation (stress/displacement) of the load. A Deformation scale text box 3224 allows the user to set the deformation scale lower or higher to visually depict more or less deformation. When Show deformation is enabled (checked) and/or the simulation is animated, this scale is applied to the deformation. The Deformation scale is based on the maximum deformation across the assembly; the default is set such that the deformation is 15% of the overall bounding box diagonal—the overall movement is always the same across any scale assembly.

A “play/pause” animation icon 3226, when selected, triggers and pauses a repeating animation of the deformation that cycles between the undeformed state shown in FIG. 32A and the deformed state shown in FIG. 32B. The animation loops as long as the animation is enabled. As it is animated, the starting position is shown as an outline of the instances, and the Assembly moves based on the applied load. The icon is a toggle. Once run, the icon switches into a stop pause icon. Pressing this stops the animation.

FIG. 32B also illustrates a set of results options 3230 in a dropdown menu from which a user can select to choose a result option. The result options can include, for example:
Von Mises Stress—A scalar value of stress that can be computed and is used to predict yielding of materials under complex loading from the results of uniaxial tensile tests. The von Mises stress satisfies the property where two stress states with equal distortion energy have an equal von Mises stress. It is a measure of energy density, as opposed to principal stress, which is a real stress. It is often used in determining whether a material yields when subjected to a complex loading condition. By default, the stress is set in MPa, but other units can be chosen.
Signed von Mises Stress—Similar to the von Mises Stress, the sign result calculates the sum of the X, Y, and Z axes normal stresses, and if the quantity is negative, a minus sign is added before the von Mises stress. By default, the stress is set in MPa.
Safety factor—Yield strength divided by the von Mises stress. This shows how the stress levels for any given instance relate to the Tensile yield strength of that instance and helps to point out problematic and non-problematic areas of stress in the simulation.
Max principal stress—Maximum principal stress is the maximum normal stress acting inside the component and its position. By default, the stress is set in MPa.
Displacement—Displays the simulation result as a measurement of displacement. By default, the displacement is set in mm.

FIG. 33 illustrates a Simulation fly-out panel 3310 that can be accessed at the far right of the window and contains a Simulation table 3312 at the top and Simulation settings 3314 at the bottom. The Simulation table 3312 is where numerical inputs for simulations, such as load values, can be viewed and edited. Additional simulations can be added as additional columns via an “Add simulation” button at the bottom of the fly out panel. For example, simulation 2 has been added to specify a different moment. The currently active simulation has its column heading highlighted and is indicated with a check. The currently active simulation can be selected or changed by a right mouse click and selection of an option to “set active” in a pop up dialog box.

In one embodiment, multiple simulations can be displayed in one or more user interface sessions (web browser windows) by the same or even multiple users to view multiple simulations on the same model. Accordingly, multiple simulations can be viewed either side by side by the same user or by different users through different user interfaces. Alternative embodiments can be configured to support display of multiple simulations, for example, in multiple tabs. Other options in the pop up dialog box can include deleting a simulation as well as moving to the left or right in the table. If there are no simulations in the Assembly, the “Add simulation” button is located at the top of the Simulation panel. When a new simulation is added, it can be accessed via the Simulation field in the Assembly list. If there are many simulations in this list, one can begin typing the name of the simulation to auto-search for the correct simulation.

Each row in the simulation table 3312 contains an entry for all simulations in the table. The following two rows display information for all the loads listed below:
Type—Indicates the simulation type (e.g., structural linear static analysis or modal analysis);
Status—Displays a warning icon when the simulation is not correct or missing information. Displays a gray exclamation icon if the simulation is ready but no results are shown.
   Displays a green checkmark when the simulation is successfully run.
   If there are multiple loads in the Simulation panel, they will be listed in order within the table. All rows contain the following information for each load:
Load name—The load name derived from the Load dialog's editable load label. Next to each load name in each row is a checkbox in each simulation column's Load table cell to enable/disable loads for that simulation.
Fx—Load component (editable value) along the x-axis of the associated mate connector.
Fy—Load component (editable value) along the y-axis of the associated mate connector.
Fz—Load component (editable value) along the z-axis of the associated mate connector.
Magnitude—Non-editable field that displays the total magnitude value derived from all 3 associated mate connector axes (Fx, Fy, and Fz).
Direction—Shows the load direction. Double-click the cell to open the Load dialog (FIG. 33A) with focus on the Load direction field. Select a new mate connector in the graphics area to update the load direction, and/or click the arrow to reverse the load direction.

The Simulation settings 3314 section of the Simulation fly-out panel 3310 enables a user to choose settings applicable to simulations. A user can select a color scheme for displaying simulations in a color scheme dropdown 3316. A user can also set up the connection method for simulations and view connections between instances in the Assembly in a Connectivity method and visualization dropdown 3320.

The Connectivity method and visualization dropdown 3320 allows a user to select from different methods used by the simulation to determine how instances in the Assembly are connected (bonded). The method chosen drives the simulation and simulation results. The methods can include, for example:
Mates and touching faces—Both mates and any touching faces are viewed as bonded by the simulation. This is the default method. Anywhere two instances touch, they interact in some manner. If mates or a Group exist between those two instances, the simulation honors whatever kinematic relation is defined by them. If no mates or Group exists, the simulation treats those regions as bonded (the same as a fastened mate or Group). This method is useful when initially constructing your model; it allows a user to systematically add mates to a model one at a time, and ensures the simulation remains sufficiently constrained.
Mates—With this method, all simulation interactions are taken strictly from mates or Groups present in the model. Any non-Mated/Grouped instances that touch each other are treated as independent bodies. During simulation, it is possible to have non-Mated instances pass through each other.
Bond all touching faces—With this method, all mates, including all Mate Simulation connections, are ignored. Any region of any instance that touches any region of any other instance is treated as bonded. This is the same behavior as adding all Assembly instances into a single Group and suppressing all mates. Though this artificially stiffens the model, it obtains immediate simulation results, and is the simplest workflow option.

FIG. 34 illustrates an expanded view of the Simulation settings 3314 section of the Simulation fly-out panel 3310 where a Show connections checklist 3402 has been selected by the user. When checked, the Show connections checklist 3402 displays the connections between instances in the Assembly graphics area as a diffuse fill color-coded by connection type, so that bonded connections are visualized. Any connection type not present in the model is grayed-out. To isolate a specific connection, a user can systematically uncheck each connection type and/or suppress mates in the Assembly list. When a type of connection does not exist in the assembly, the connection type is grayed out. If it exists, it is available to check (show) or uncheck (hide). If multiple connection types are in use in the same locations, they are color-coded yellow. The connection types can include, for example, the following.
Fastened—When checked, Fastened Mate connections are shown. Fastened Mate connections bond two instances across their interface. Instances deform in unison; no relative displacement is permitted across this interface.
Simulation bonded—When checked, simulation bonded connections are displayed. Simulation bonded connections are only possible when Method is set to Mates and touching faces or Bond all touching faces. Simulation bonded acts the same as Fastened.
Group—When checked, instance groupings are displayed. All instances within a Group connection are treated as though Fastened across each of their interfaces.
Revolute—When checked, Revolute Mate connections are displayed. Revolute Mate connections prohibit any relative motion between two instances across their interface, except for rotations about the Revolute center axis.
Slider—When checked, Slider Mate connections are displayed. Slider Mate connections prohibit any rotational relative motion between instances across their interface, as well as translational relative motion across the interface, except along a singular (sliding) direction.
Planar—When checked, Planar Mate connections are displayed. Planar Mate connections prohibit any rotational relative motion between instances across their interface, as well as any out-of-plane translational relative motion between instances.
Cylindrical—When checked, Cylindrical Mate connections are displayed. Cylindrical Mate connections allow rotational/translational relative motion between instances across their interface about/along the cylindrical center axis. All other relative motion is prohibited.
Ball—When checked, Ball Mate connections are displayed. Ball Mate connections prohibit any translational relative motion between instances across their interface, though they allow any and all rotational relative motion about the ball center point.
Not connected—When checked, instances that are within simulation interaction proximity and could be connected but are not (they do not have any prescribed simulation interaction) are displayed and color-coded red. If two adjacent instances are not meant to interact with each other, disregard the Not connected visualization. Conversely, the ability to identify any Not connected instances is useful as the user builds up their assembly mates for the first time by showing you missing connections.
Multiple connection types—This is only displayed if multiple connection types are in use in the same location, as is often the case when multiple instances are joined closely together. These connections are color-coded yellow. This category considers Not Connected to be a valid interaction type. For example, if the corner of a instance A is fastened to instance B and adjacent to instance C, but no interaction is defined between A and C, then instance A's corner is marked as a Multiple connection type (colored yellow), unless either the Fastened or Not Connected visualization box is unchecked.

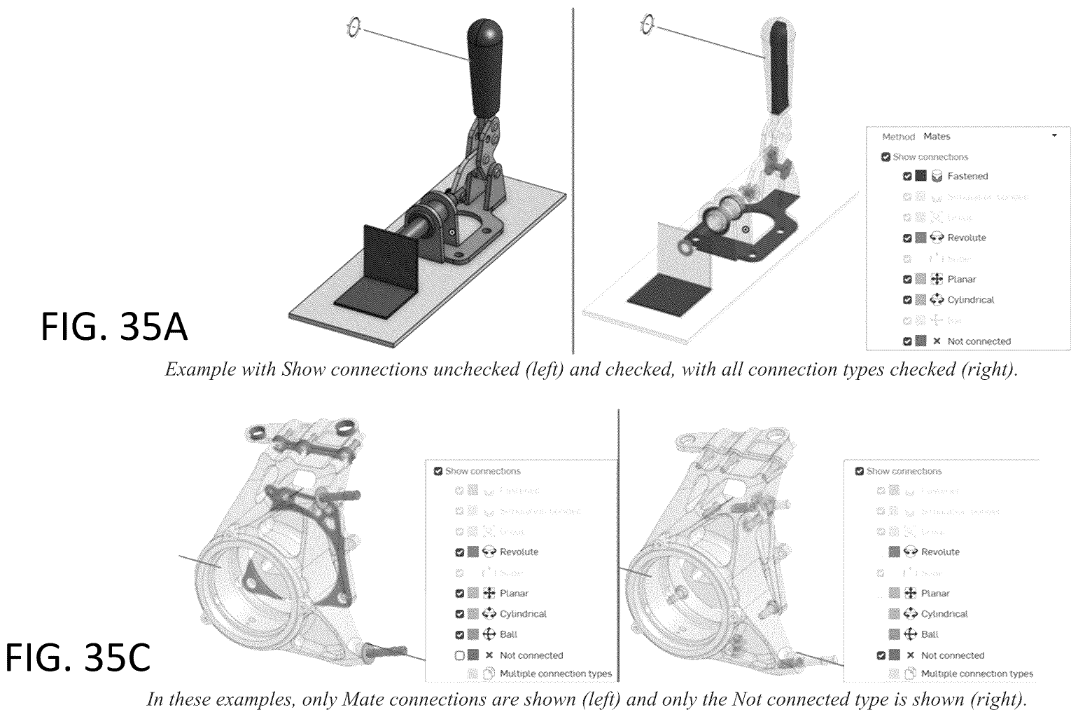

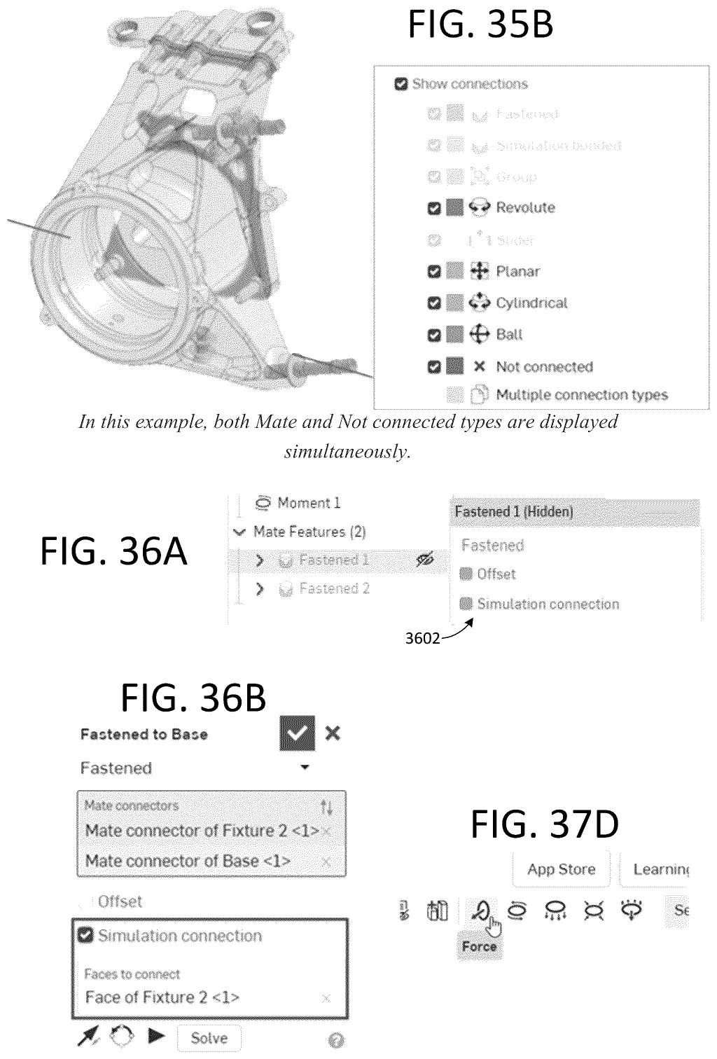

FIGS. 35A-C illustrate three examples of the use of the Show connections checklist 3402. The illustrations of FIGS. 35A-C are intended to provide a general picture of the use of the Show connections checklist 3402, and specific text in these examples is not material or intended to be legible.

FIGS. 36A-B illustrate a Mate Simulation connection option 3602, which can be found at the bottom of the Mate dialog (except Pin slot, Parallel, and Tangent Mate dialogs) in the Assembly list. This option provides a greater degree of precision and control over which regions are bonded by limiting the mate's effect over a specific region, as opposed to having the mate bond anywhere two mated instances touch. A user can check the Simulation connection option and enter the Faces to connect as shown in FIG. 36B. Simulation connection has no impact on typical Assembly modeling behavior; it is only seen during simulation. A user can use Simulation connections to inspect the difference. Using Bond all touching faces as the Simulation connection method overrides all Mate Simulation connections.

Example Simulation User Workflow

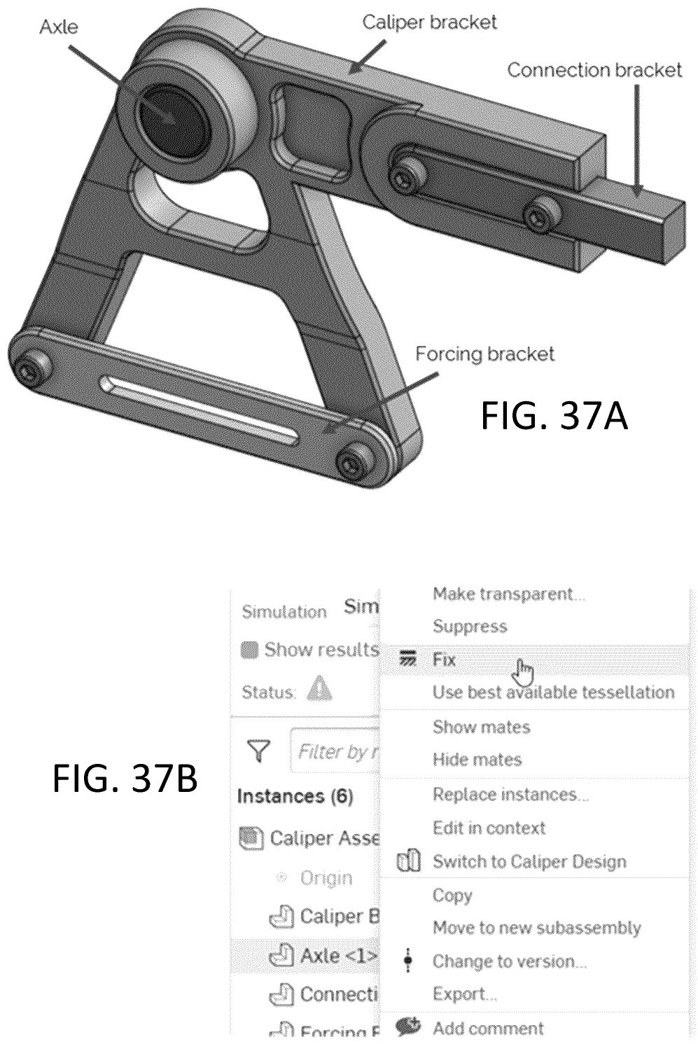

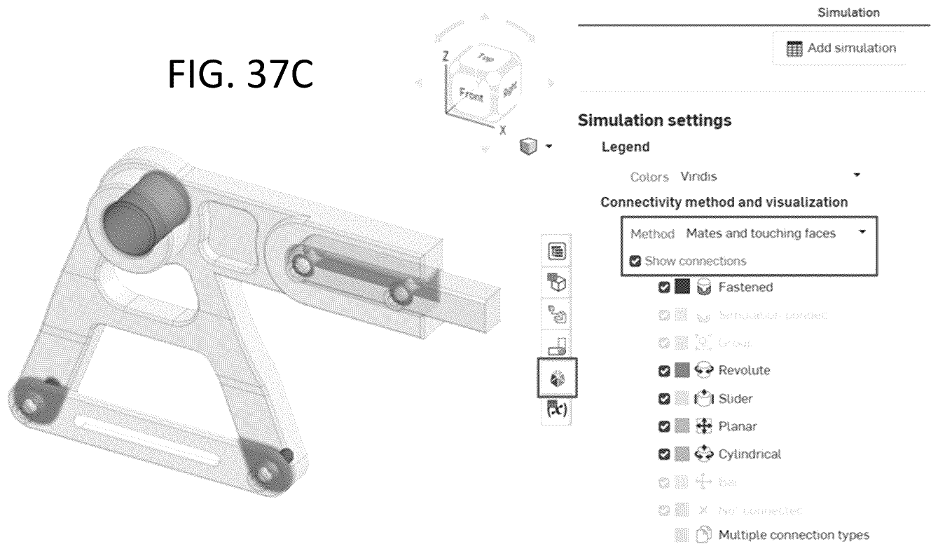

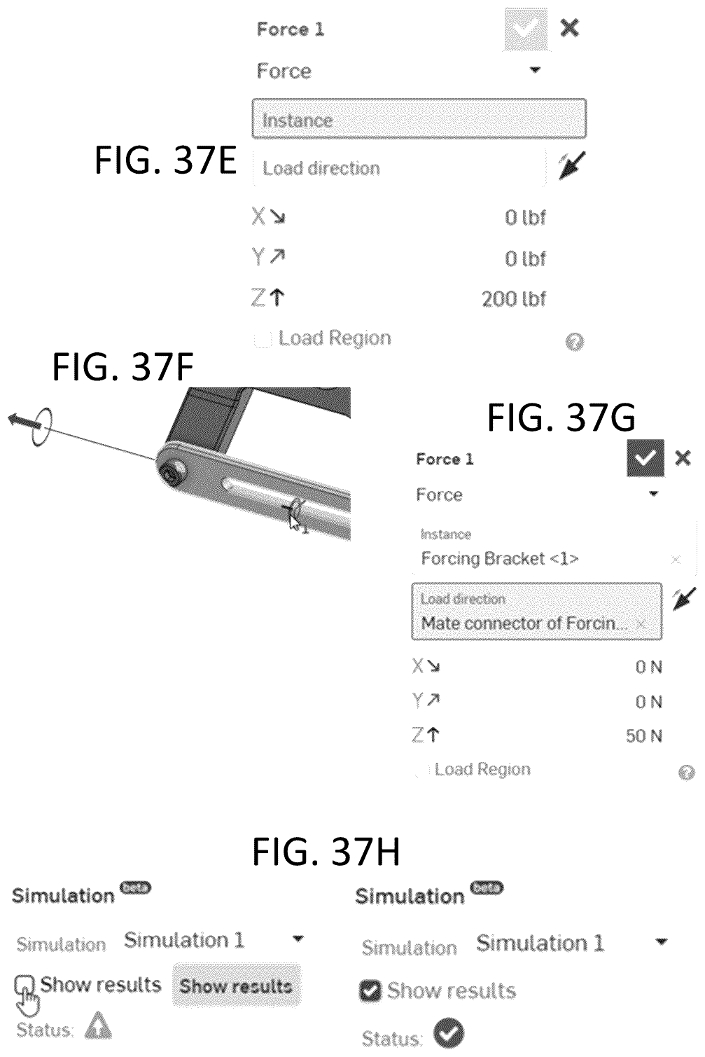

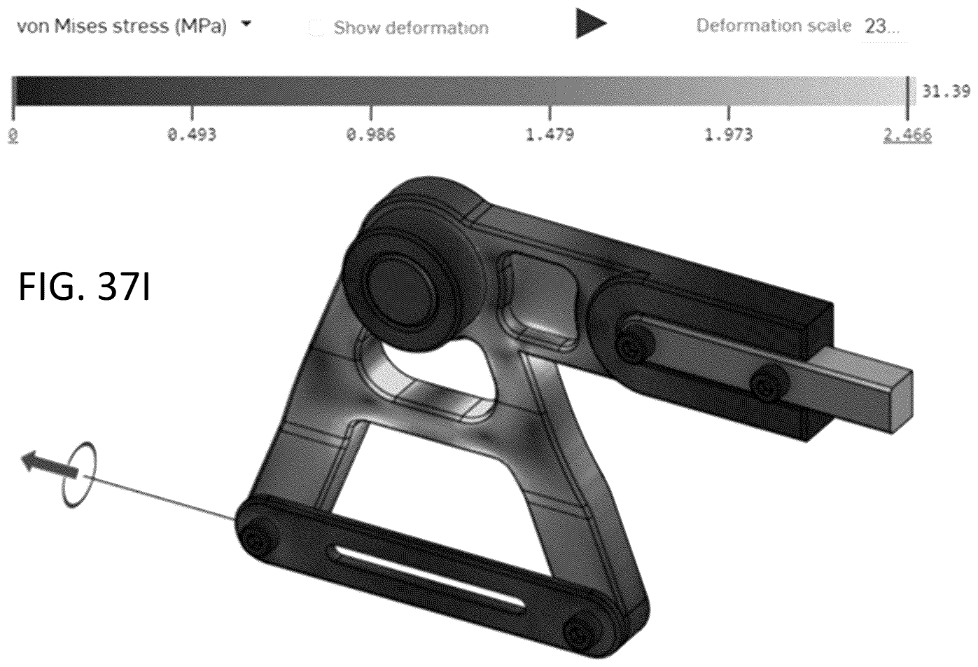

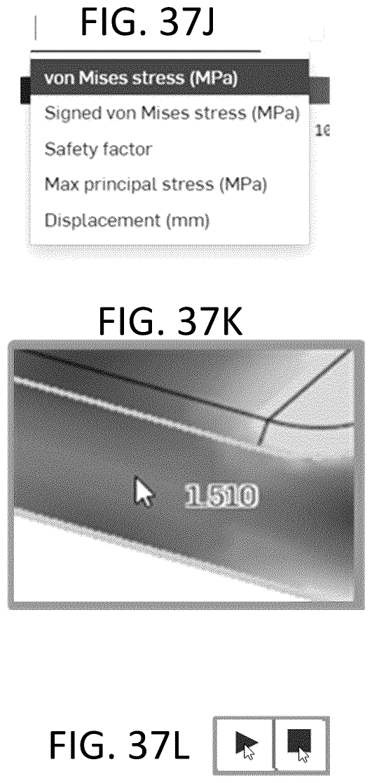

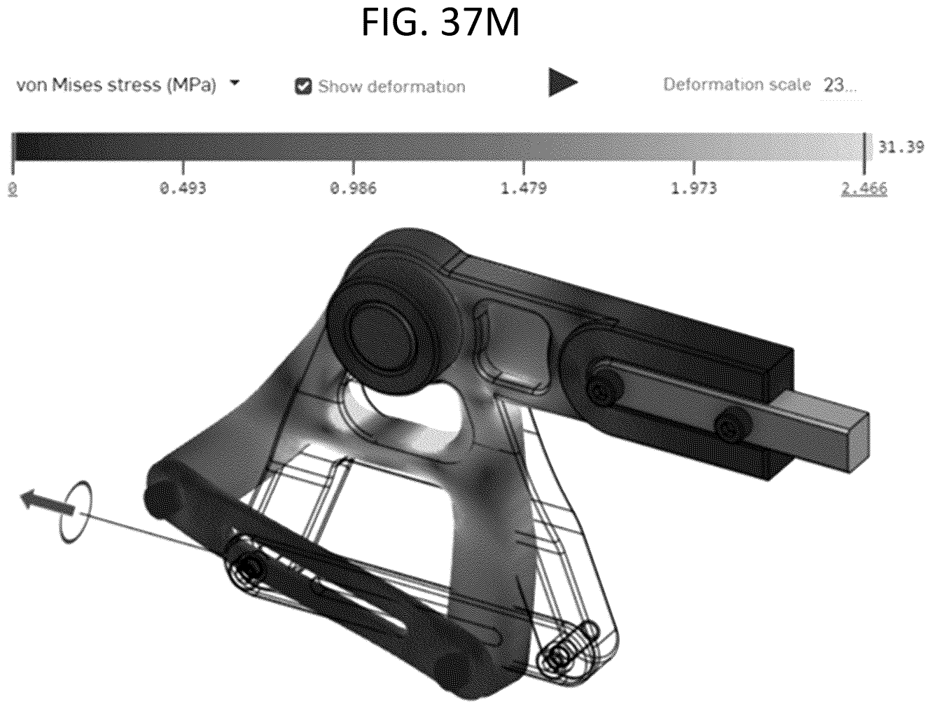

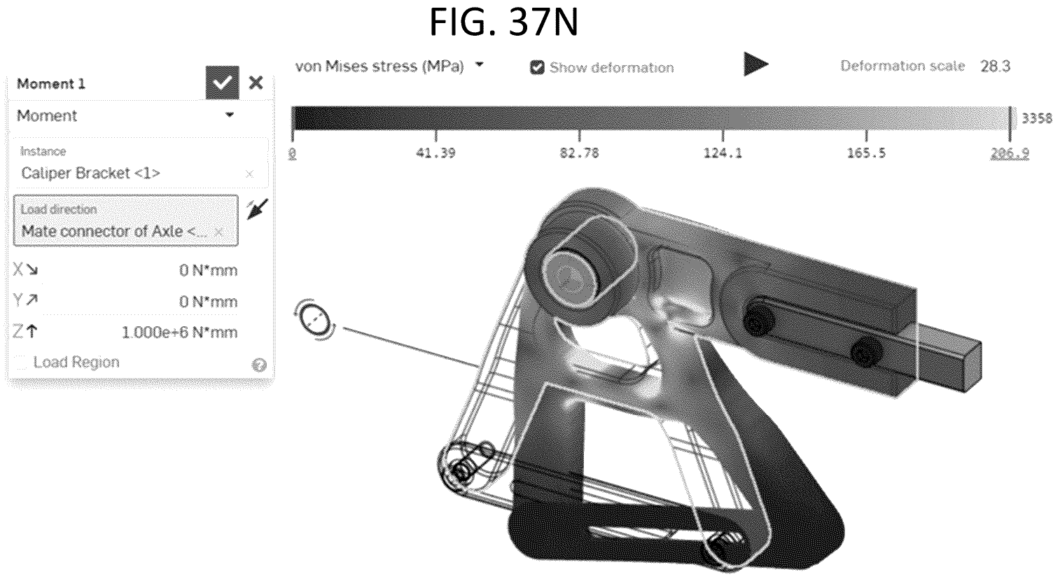

FIGS. 37A-N illustrate a workflow to create and simulate a load on a CAD model. This workflow assumes a user has a completed CAD model in an Assembly tab, with the instances mated and the assembly sufficiently constrained. For this simulation example, a Caliper bracket assembly is used. It contains four instances and four bolts. The four instances are: the Caliper bracket, Axle, Connection bracket, and Forcing bracket (FIG. 37A). Before creating a simulation, the following two criteria must be met. First, when performing a structural linear static analysis, for example, at least one instance must be fixed in the Assembly. This is the instance on which the load is bearing. Right-click on the Axle and select Fix from the context menu (FIG. 37B). Do the same for the Connection bracket instance. Second, all instances (including standard content) used in the simulation (except those that are fixed) require a material assigned to them (if not already assigned as part of the design process). In this instance, the user selects each part in the Assembly and chooses a material though a set of menus (not illustrated).

Next a user can visualize the mate connections in the assembly by opening the Simulation panel and checking Show connections (FIG. 37C). If desired, the user can select an alternate Method to determine how instances in the assembly are connected (bonded together). Simulation connections can be visualized, and the Method used can be changed at any point before, during, and after the simulation. From the Assembly tab, select one of the five load tools (Force is selected in this example) along the top right of the Assembly toolbar (FIG. 37D) to open the Force dialog (FIG. 37E). The user selects an Instance. In one embodiment, only one instance can be selected as multiple instances are not supported; however, a user can create multiple simulation loads in the same assembly. For this example, the Forcing bracket instance is selected. The user next selects a Load direction by selecting an existing mate connector or clicking on a location to create a new one that drives the load direction. The user can click the reverse arrow icon to reverse the direction of the load. For this example, a mate connector is added to the edge of the Forcing bracket, with the Z axis pointing left (FIG. 37F). By default, the load is applied to the whole body. If desired, optionally check Load region, and select instance faces to narrow the load to a specific region. Click the green checkmark to close the Force dialog and check Show results. As the results are calculated, a blue progress bar indicates the time remaining before the final calculation displays. Early iterations are displayed in the stress scale. When finished, the blue progress bar reads complete, and then a green checkmark is placed next to the Status signifying the calculation (convergence) is complete (FIG. 37H).

The simulation converts the Assembly geometry to a simulation mesh and begins the first of five adaptive passes before converging on a result. Intermediate updates are streamed through the browser, giving you early simulation results. When results are finalized, the Scale is visible at the top of the screen, and the stress plot overlays the loaded instances in the graphics area with a color gradient (FIG. 37I). Simulation results are also temporarily cached. The user can then select from five different result metrics (FIG. 37J). Hovering a mouse over the instance in the graphics area will display a numerical readout next to the cursor (FIG. 37K). This indicates the stress or displacement amount of the instance located under the cursor. To animate the simulation, click the play toggle above the color scale (FIG. 37L). To stop playback, press the stop toggle.

FIG. 37M illustrates the simulation load result with Show deformation checked. The deformation is overlaid with a view of the original assembly as a wire frame.

FIG. 37N displays an alternate simulation load using Moment, selecting the caliper bracket as the instance, and then selecting the mate connector at the center point of the axle as the Load direction. A load of 1.000e+6 N*mm is applied along the Z axis, and Show deformation is checked in the legend. This shows both the original Assembly and resultant deformation at the same time.

Alternative Simulation Example

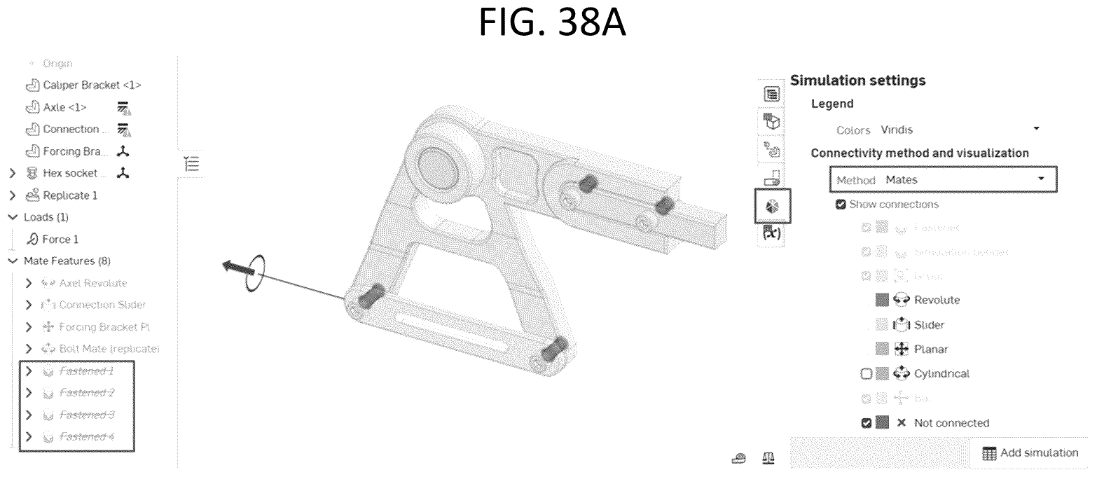

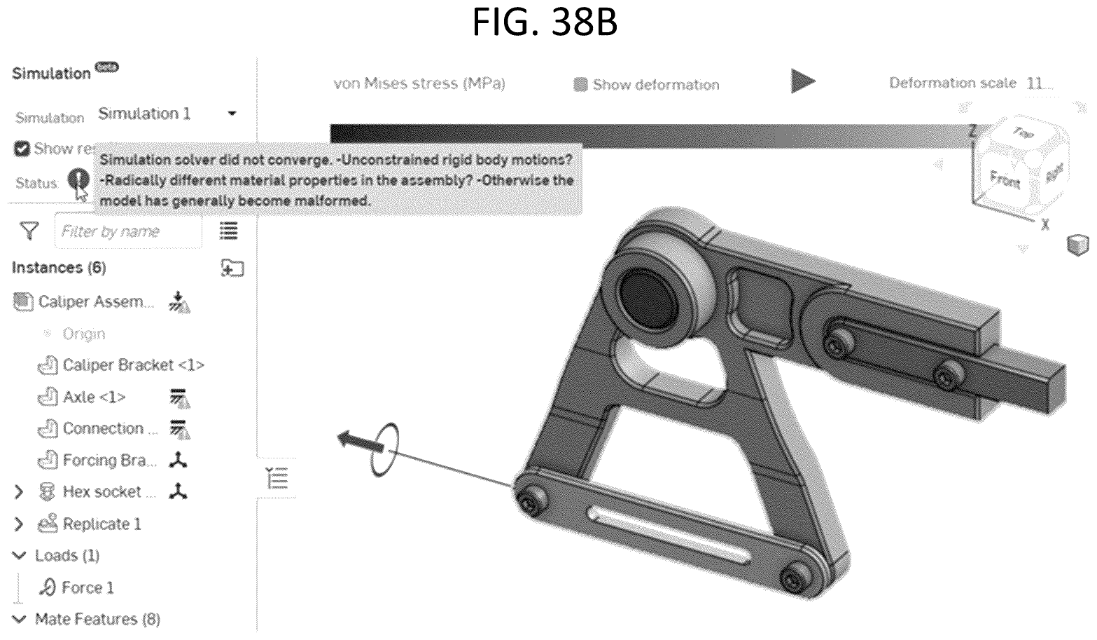

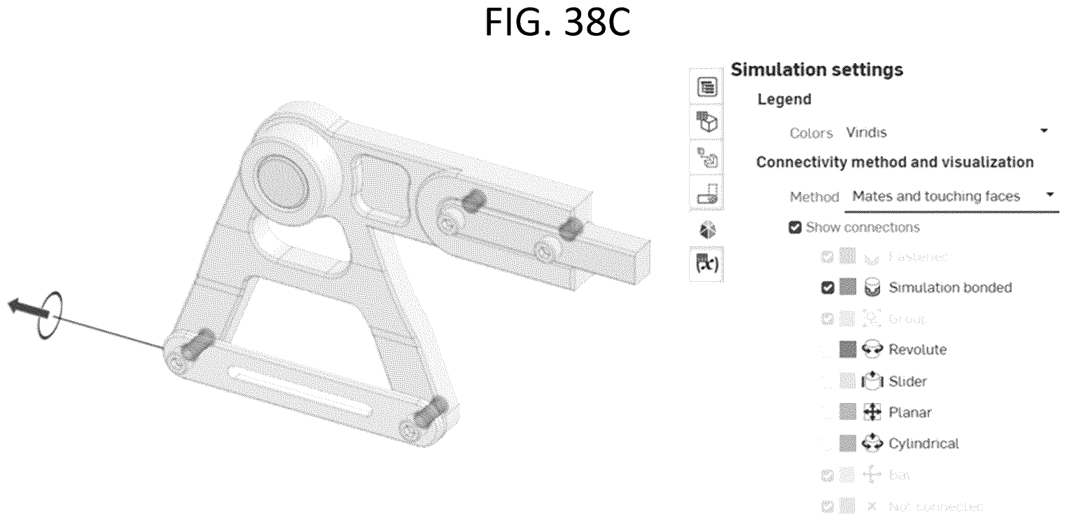

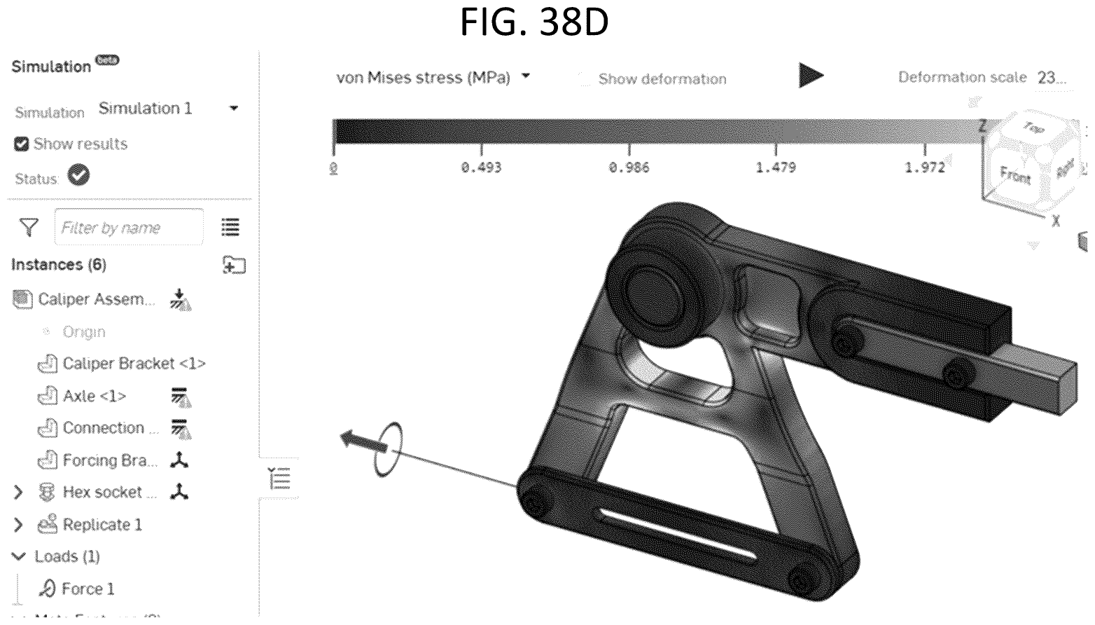

FIGS. 38A-D illustrate an alternate method to solve a simulation. For this example, the same Caliper bracket assembly is used from the workflow section above as shown in FIGS. 37A-N. In FIG. 38A, mates are used as the Simulation connection method, and the Fastened Mates that connect the bolts between the Caliper bracket and Forcing bracket are suppressed in the Mate Features list. There is nothing to constrain the Forcing bracket to the Caliper bracket. In FIG. 38B, the user checks Show results in the Simulation panel at the top left, but the Simulation solver does not converge due to unconstrained rigid body motions. In FIG. 38C, the user changes the Simulation connections Method to Mates and touching faces. The touching faces between the bolts and Caliper bracket are treated as “simulation bonded”; the simulation is now fully constrained and can be solved. In FIG. 38D, the user checks Show results in the Simulations panel at the top left to view the Simulation results.

Simulation Assumptions and Inferences

In certain embodiments, interactions between instances are inferred wherever two instances touch. If two instances are not touching (or within very close proximity), they do not interact with one another when simulated. By default, any two instances which touch and are not otherwise mated are assumed to be bonded together. If mated, then the bonded behavior is overruled by the kinematic relation prescribed by the mate.

Comparison With Traditional Simulation Workflows

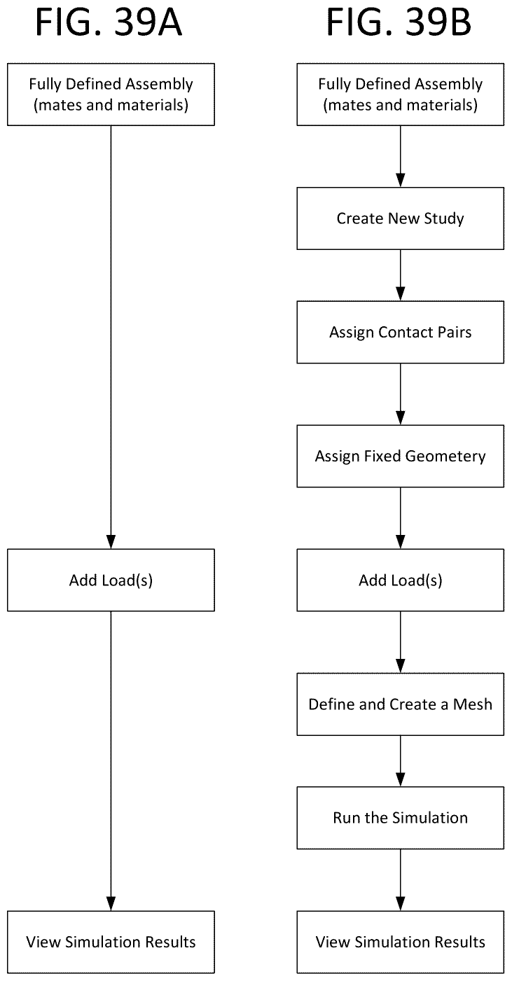

FIGS. 39A-B contrast the simulation workflow of the disclosed system (FIG. 39A) and a traditional simulation workflow (FIG. 39B). From a user's perspective, the disclosed system environment enables a user to simply apply loads to a fully defined assembly and view the results of their simulation. A traditional FEA workflow, however, might include the following steps:
Export CAD data, often just one part, to import into FEA software to build a separate simulation model.
Preprocess CAD to simplify model to reduce computational time, such as removing small features like filets or fasteners.
Mesh the model to build a new, abstracted representation for simulation.
Apply materials.
Apply loads and constraints.
Apply boundary conditions.
Select and set up FEA solver with properties and settings.
Solve and monitor quality of results.
Post-process and inspect results.

Computer Implementation

Components of the embodiments disclosed herein, which may be referred to as methods, processes, applications, programs, modules, engines, functions or the like, can be implemented by configuring one or more computers or computer systems using special purpose software embodied as instructions on a non-transitory computer readable medium. The one or more computers or computer systems can be or include one or more standalone, client and/or server computers, which can be optionally networked through wired and/or wireless networks as a networked computer system.

The special purpose software can include one or more instances thereof, each of which can include, for example, one or more of client software, server software, desktop application software, app software, database software, operating system software, and driver software. Client software can be configured to operate a system as a client that sends requests for and receives information from one or more servers and/or databases. Server software can be configured to operate a system as one or more servers that receive requests for and send information to one or more clients. Desktop application software and/or app software can operate a desktop application or app on desktop and/or portable computers. Database software can be configured to operate one or more databases on a system to store data and/or information and respond to requests by client software to retrieve, store, and/or update data. Operating system software and driver software can be configured to provide an operating system as a platform and/or drivers as interfaces to hardware or processes for use by other software of a computer or computer system. By way of example, any data created, used or operated upon by the embodiments disclosed herein can be stored in, accessed from, and/or modified in a database operating on a computer system.

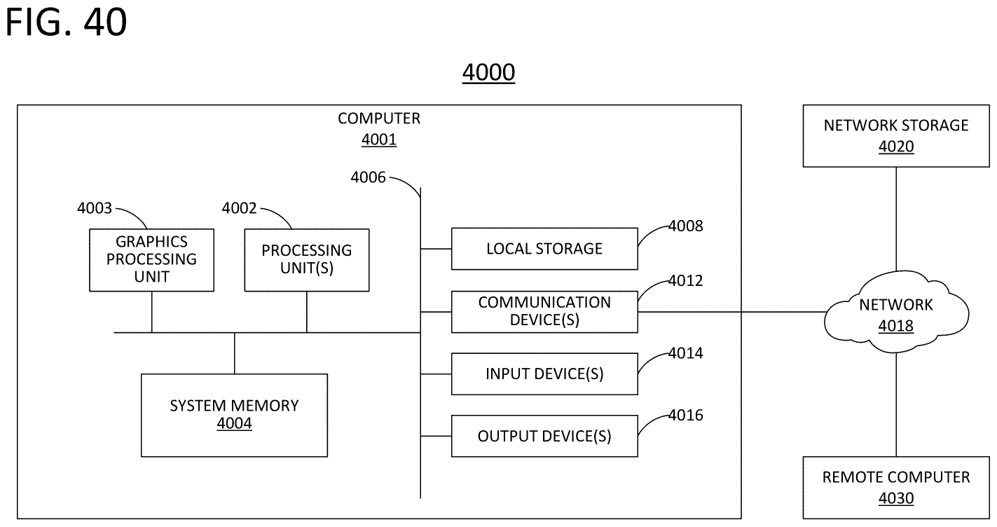

FIG. 40 illustrates a general computer architecture 4000 that can be appropriately configured to implement components disclosed in accordance with various embodiments. The computing architecture 4000 can include various common computing elements, such as a computer 4001, a network 4018, and one or more remote computers 4030. The embodiments disclosed herein, however, are not limited to implementation by the general computing architecture 4000.

Referring to FIG. 40, the computer 4001 can be any of a variety of general purpose computers such as, for example, a server, a desktop computer, a laptop computer, a tablet computer or a mobile computing device. The computer 4001 can include a processing unit 4002, a system memory 4004 and a system bus 4006.

The processing unit 4002 can be or include one or more of any of various commercially available computer processors, which can each include one or more processing cores that can operate independently of each other. Additional co-processing units, such as a graphics processing unit 4003, also can be present in the computer.

The system memory 4004 can include volatile devices, such as dynamic random access memory (DRAM) or other random access memory devices. The system memory 4004 can also or alternatively include non-volatile devices, such as a read-only memory or flash memory.

The computer 4001 can include local non-volatile secondary storage 4008 such as a disk drive, solid state disk, or removable memory card. The local storage 4008 can include one or more removable and/or non-removable storage units. The local storage 4008 can be used to store an operating system that initiates and manages various applications that execute on the computer. The local storage 4008 can also be used to store special purpose software configured to implement the components of the embodiments disclosed herein and that can be executed as one or more applications under the operating system.

The computer 4001 can also include communication device(s) 4012 through which the computer communicates with other devices, such as one or more remote computers 4030, over wired and/or wireless computer networks 4018. Communications device(s) 4012 can include, for example, a network interface for communicating data over a wired computer network. The communication device(s) 4012 can include, for example, one or more radio transmitters for communications over Wi-Fi, Bluetooth, and/or mobile telephone networks.

The computer 4001 can also access network storage 4020 through the computer network 4018. The network storage can include, for example, a network attached storage device located on a local network, or cloud-based storage hosted at one or more remote data centers. The operating system and/or special purpose software can alternatively be stored in the network storage 4020.

The computer 4001 can have various input device(s) 4014 such as a keyboard, mouse, touchscreen, camera, microphone, accelerometer, thermometer, magnetometer, or any other sensor. Output device(s) 4016 such as a display, speakers, printer, or eccentric rotating mass vibration motor can also be included.

The various storage 4008, communication device(s) 4012, output device(s) 4016 and input device(s) 4014 can be integrated within a housing of the computer or can be connected through various input/output interface devices on the computer, in which case the reference numbers 4008, 4012, 4014 and 4016 can indicate either the interface for connection to a device or the device itself as the case may be.

Any of the foregoing aspects may be embodied in one or more instances as a computer system, as a process performed by such a computer system, as any individual component of such a computer system, or as an article of manufacture including computer storage in which computer program instructions are stored and which, when processed by one or more computers, configure the one or more computers to provide such a computer system or any individual component of such a computer system. A server, computer server, a host or a client device can each be embodied as a computer or a computer system. A computer system may be practiced in distributed computing environments where operations are performed by multiple computers that are linked through a communications network. In a distributed computing environment, computer programs can be located in both local and remote computer storage media.

Each component of a computer system such as described herein, and which operates on one or more computers, can be implemented using the one or more processing units of the computer and one or more computer programs processed by the one or more processing units. A computer program includes computer-executable instructions and/or computer-interpreted instructions, such as program modules, which instructions are processed by one or more processing units in the computer. Generally, such instructions define routines, programs, objects, components, data structures, and so on, that, when processed by a processing unit, instruct the processing unit to perform operations on data or configure the processor or computer to implement various components or data structures.

Components of the embodiments disclosed herein, which may be referred to as modules, engines, processes, functions or the like, can be implemented in hardware, such as by using special purpose hardware logic components, by configuring general purpose computing resources using special purpose software, or by a combination of special purpose hardware and configured general purpose computing resources. Illustrative types of hardware logic components that can be used include, for example, Field-programmable Gate Arrays (FPGAs), Application-specific Integrated Circuits (ASICs), Application-specific Standard Products (ASSPs), System-on-a-chip systems (SOCs), and Complex Programmable Logic Devices (CPLDs).

### Glossary

Assembly—used to assemble parts. An Assembly is used to define the structure and behavior of an assembly. Each Assembly has its own Feature list that contains Instances (of parts and sub-assemblies), Mates, Mate Connectors, Groups, and Relations.

Back up geometry—reference to prior geometry which has been changed.

Branch—workspace for a specific version of a project.

Client Device—computer hardware, such as a desktop computer, tablet, phone, or wearable computer such as glasses or watch, used by a user of the system for three-dimensional multi-user computer aided design.

Client Program—software program running on a client device to access the multi-user cloud CAD system and to provide an interface to a user for interacting with the multi-user cloud CAD system. The software program may be a dedicated application or a web-page driven interface running within a browser.

Compound Document—a single data structure which is actually made up of any number of internal components which traditionally would be stored as separate files.

Compound inference—an inference that is composed of multiple inferences.

Constraint—a relationship between two geometries that mutually limits their positions, e.g., a “coincident” constraint on two points will result in the points having the same location. There are many types of constraints, such as coincident, parallel, perpendicular, tangent and so on. Constraints are logical relationships between geometries. For example, a “parallel” constraint between two line segments will ensure that the two line segments are parallel.

Degrees of freedom—data associated with geometry that explains how or if that geometry may be repositioned by the solver. For example, a point may be constrained to lie on a fixed line. In such a case its degrees of freedom is translation along that line.

Derivatives—the approximation of the rate of change of a sketch state vector with respect to a dragged geometry state vector.

Dragged Geometry—the geometry being dragged by the user, where dragged means that the user is moving the geometry in some way, such as by clicking and dragging with a mouse or dragging with a finger or stylus on a touch enabled device.

Dragged Geometry State Vector—a subset of a sketch state vector that represents the dragged geometry.

Features—rules or properties configured for a part or an assembly. Features may reference other features as part of their definition.

Feature List—In Part Studios: a parametric history of work, containing features, parts, and a Rollback bar to view work at a certain point in the parametric history; In Assemblies, the Feature list contains an Assembly Instance tree structure, Mates, Groups, and Mate connectors.

Geometry—solid bodies, surfaces, axes, curves, or points and other pieces of shapes that the user can manipulate and which the software will reposition to satisfy constraints. For example, a line segment is a line (straight curve) between two points.

Persistent Transaction History—a set of retained states of all tabs (Part Studio, Assemblies, etc.) of a workspace at each persisted change made within any tab.

In-context reference—within a CAD design program, references that are relationships between geometric objects that are created in separate parametric histories in the context of an assembly are referred to as “in-context” references.

Instance—a reference within an Assembly to either a part defined in a Part Studio, or to a sub-assembly defined in another Assembly.

Inference—a constraint that is detected during sketching and which can be added to the model when geometry is created or repositioned. For example, when drawing a new line, a coincident inference might be found between an end of that line and an existing point in the model.

Mate—a high-level entity used to position instances and define how the instances move (e.g., define movement between parts and/or sub-assemblies).

Mate connectors—local coordinate system entities located on or between parts and used within a mate to locate and orient instances with respect to each other (define where instances connect).

Model—the 3D geometry that is the result of the geometric operations.

Out of sync reference—when referenced geometry or the context that defines the position of referenced geometry changes, the “in-context reference” is called “out of sync”.

Parametric history—ordered list of features that when regenerated in order creates geometry of one or more parts.

Part—a named geometric construction, which can be combined and constrained with other parts to create an assembly.

Part Studios—where a user creates parts. A Part Studio contains a Feature list (parametric history) and a list of parts generated by that feature list.

Project—a Compound Document within the 3D CAD system.

Reference—relationship between design geometry.

Sketch—a collection of 2D geometry and constraints, on a plane.

Sketch State Vector—a vector of numbers that represents all of the geometry in a sketch.

Sketching—the action of modifying a sketch.

Sketcher—a software component that the user uses to create and manipulate geometry and constraints.

Solver—a software component used by the sketcher that takes a collection of geometry and a collection of constraints and repositions geometry as necessary to satisfy the constraints.

Snap—adjustment of geometry so that it coincides with an inference.

Surfaces—Surfaces individually or in sets can be parts or construction entities and may be used or referenced by various sketching and part modification tools in order to alter or create parts.

The System—one or more interconnected or network connected servers working with one or more Clients across network connections to operate multi-user parametric feature based three-dimensional computer aided design.

Tab—represents an individual design or documentation component stored within a compound document for a project. For example, a tab could represent a Part Studio, an Assembly, a Drawing, or an uploaded file such as a pdf, image, video, or any file stored as it would be in on a computer disk.

Version—a named state of a compound document. Versions are immutable and separate from workspaces. To capture a workspace at a particular point in time, a user can save it as a version.

Workspace—An active modeling/design space.

### CONCLUSION

Although the subject matter has been described in terms of certain embodiments, other embodiments that may or may not provide various features and aspects set forth herein shall be understood to be contemplated by this disclosure. The specific embodiments set forth herein are disclosed as examples only, and the scope of the patented subject matter is defined by the claims that follow.

In the claims, the terms “based upon” and “based on” shall include situations in which a factor is taken into account directly and/or indirectly, and possibly in conjunction with other factors, in producing a result or effect. In the claims, a portion shall include greater than none and up to the whole of a thing. In method claims, any reference characters are used for convenience of description only, and do not indicate a particular order for performing a method.

1. A method performed by a computer system having at least one processor and a memory, the method comprising, the computer system:
maintaining in the memory a computer-aided design (CAD) model representing a plurality of components of a modeled object;
receiving a user request to perform a simulation on or of the CAD model, the user request being received through a unified simulation and CAD modeling environment;
performing an automated analysis of the CAD model to identify portions of the model that have one or more restricted degrees of freedom; and
performing a simulation on the CAD model, wherein the simulation accounts for the one or more restricted degrees of freedom.

2. The method of claim 1, wherein the automated analysis of the CAD model comprises:
identifying portions of different components of the CAD model that are positioned within a predetermined distance of each other within the modeled object; and
identifying the one or more restricted degrees of freedom based on the identified portions of different components.

3. The method of claim 2, wherein identifying portions of different components of the CAD model that are positioned within a predetermined distance of each other within the modeled object comprises:
converting the CAD model from a boundary representation format to a volumetric representation format; and
identifying regions where volumetric representations of components intersect.

4. The method of claim 1, further comprising:
receiving user input through a CAD user interface, the user input defining one or more loads upon the model; and
storing definitions of the one or more loads in as data elements within the CAD model.

5. The method of claim 1, wherein the plurality of components are related in the CAD model by connection points having associated connection types, and wherein the simulation on the CAD model accounts for further restricted degrees of freedom based on the connection points and associated connection types.

6. The method of claim 1, wherein the simulation is of a type selected from the group consisting of:
structural linear static analysis, and
modal analysis.

7. A method performed by a computer system having at least one processor and a memory, the method comprising, the computer system:
maintaining a computer-aided design (CAD) model comprising a plurality of components in the memory, wherein the plurality of components are related by connection points having associated connection types;
performing an automated analysis to identify portions of different components that are positioned within a predetermined distance within the CAD model; and
based on the automated analysis, restricting one or more degrees of freedom of the identified portions of different components in a simulation environment.

8. A method performed by a computer system having at least one processor and a memory, the method comprising, the computer system:
maintaining in the memory a computer-aided design (CAD) model representing a plurality of components of a modeled object;
receiving a user request to perform a simulation on the CAD model in a unified simulation and CAD modeling environment;
performing an automated analysis of the CAD model to identify portions of different components that are positioned within a predetermined distance of each other within the modeled object;
based on the automated analysis, restricting one or more degrees of freedom of the identified portions of different components in the unified simulation and CAD modeling environment; and
performing a simulation on the CAD model, wherein the simulation accounts for the restricted one or more degrees of freedom.
